(19) United States
(12) Patent Application Publication
(10) Pub. No.: US 2025/0188587 A1
(43) Pub. Date: Jun. 12, 2025

(54) RADICAL SPECIES RECOMBINATION IN SUBSTRATE PROCESSING SYSTEMS

(71) Applicant: Applied Materials, Inc., Santa Clara, CA (US)

(72) Inventors: Jia Pelpa, Sunnyvale, CA (US); Joseph Frederick Behnke, San Jose, CA (US); Christopher Laurent Beaudry, San Jose, CA (US); Hari K. Ponnekanti, San Jose, CA (US)

(21) Appl. No.: 18/973,504

(22) Filed: Dec. 9, 2024

Related U.S. Application Data
(60) Provisional application No. 63/608,345, filed on Dec. 11, 2023.

(51) Int. Cl. C23C 14/06; C23C 14/02; C23C 14/28; C23C 14/48

(52) U.S. Cl. CPC C23C 14/0694; C23C 14/02; C23C 14/28; C23C 14/48

(57) ABSTRACT

A system includes a plasma source to generate a plasma including radical species, at least one component, associated with the plasma source, coated with a protective coating including fluorinated magnesium that mitigates recombination of the radical species, and a radical sensor including a filter disposed on a piezoelectric material to selectively react with the radical species.

### CROSS-REFERENCE TO RELATED APPLICATION(S)

The present application claims priority to U.S. Provisional Patent Application No. 63/608,345, filed on Dec. 11, 2023 and entitled “RADICAL SPECIES RECOMBINATION IN SUBSTRATE PROCESSING SYSTEMS”, the entire contents of which are hereby incorporated by reference herein.

### TECHNICAL FIELD

The instant specification relates to components and apparatuses for semiconductor manufacturing. More specifically, the instant specification relates to radical species recombination in substrate processing systems.

### BACKGROUND

Electronic devices, such as integrated circuits, are made possible by processes which produce intricately patterned material layers on substrate surfaces. Forming patterned material layers on a substrate can be performed using controlled methods for forming and removing material. Such methods can use gases to deposit layers, etch layers, clean substrates, and so on. Some processes are plasma-based or plasma-enhanced processes (e.g., deposition, etching, cleaning), during which a plasma can be generated by a plasma source. For example, a plasma source can be a remote plasma source (RPS) external to a processing chamber. To perform a plasma-based process (e.g., deposition process, etch process or clean process), one or more precursors may be mixed in a gas panel and delivered to a processing region of the processing chamber where a substrate may be disposed. For example, plasma can be generated using an inductively coupled plasma (ICP) source and/or a capacitively coupled plasma (CCP) source.

For some plasma-based processes, the plasma source (e.g., RPS) can generate a plasma containing radical species. Radical species can include electrically neutral particles (e.g., atoms) produced by collisions between electrons and gas molecules. One example of radical species are fluorine radicals including atomic fluorine (F). For example, plasma can convert a gas or gas mixture including a fluorine-containing gas into fluorine radicals. Illustratively, fluorine radicals can be used to etch a silicon (Si) substrate.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular implementations of the disclosure or any scope of the claims. Its sole purpose is to present some concepts of the disclosure in a simplified form as a prelude to the more detailed description that is presented later.

In some embodiments, a system is provided. The system includes a plasma source to generate a plasma including radical species, at least one component, associated with the plasma source, coated with a protective coating including fluorinated magnesium that mitigates recombination of the radical species, and a radical sensor including a filter disposed on a piezoelectric material to selectively react with the radical species.

In some embodiments, a method is provided. The method includes obtaining a component associated with a plasma source, and forming, on a surface of the component, a protective coating including fluorinated magnesium that prevents recombination of at least one radical species.

In some embodiments, a method is provided. The method includes initiating a plasma-based process of a substrate processing system, and causing a plasma source to generate a plasma including radical species to perform the plasma-based process. The plasma source is associated with one or components coated with a protective coating including fluorinated magnesium that prevents recombination of the radical species.

### BRIEF DESCRIPTION OF THE DRAWINGS

The present disclosure is illustrated by way of example, and not by way of limitation in the figures of the accompanying drawings.

FIG. 1 is a sectional side view of an example substrate processing system including a radical sensor, according to some embodiments.

FIGS. 2A-2B are views of an example radical sensor device for radical species detection, according to some embodiments.

FIGS. 3A-3D are views of an example radical sensor for radical species detection, according to some embodiments.

FIGS. 4A-4B are cross-sectional views of the formation of an example radical sensor for radical species detection, according to some embodiments.

FIG. 5 is a cross-sectional view of an example radical sensor for radical species detection, according to some embodiments.

FIG. 6 shows an example equivalent circuit for a radical sensor for radical species detection, according to some embodiments.

FIG. 7 is a diagram of an example substrate processing system including at least one component having a protective coating for minimizing radical species recombination and extending radical species lifetime, according to some embodiments.

FIG. 8 is a flowchart of an example method for forming a protective coating on at least one component of a substrate processing system for minimizing radical species recombination and extending radical species lifetime, according to some embodiments.

FIG. 9 is a diagram of an example component of a substrate processing system coated with a protective coating for minimizing radical species recombination and extending radical species lifetime, according to some embodiments.

FIG. 10 is a flowchart of an example method for utilizing a substrate processing system for minimizing radical species recombination and extending radical species lifetime, according to some embodiments.

FIG. 11 is a flowchart of an example method for utilizing an acoustic resonance sensor device for radical species detection, according to some embodiments.

FIG. 12A is a chart illustrating example measurements taken by a radical sensor without using a protective coating, according to some embodiments.

FIG. 12B is a chart illustrating example measurements taken by a radical sensor using a protective coating, according to some embodiments.

### DETAILED DESCRIPTION

Embodiments of the present disclosure relate to radical species recombination in substrate processing systems. Radical species within plasma generated by a plasma source (e.g., RPS) can be transported from the plasma source to a processing chamber via a line, and can be delivered into the processing chamber using a gas distribution assembly (e.g., showerhead). However, the radical species can chemically react to the surfaces of various components of the substrate processing system (e.g., processing chamber wall, gas distribution assembly, the plasma source, and/or one or more components connected to the plasma source), which can reduce radical species availability. Additionally, radical species can stick to surfaces of various components of the substrate processing system as they are transported, which can enable recombination of the radical species.

To address these and other drawbacks, embodiments described herein can be used to minimize radical species recombination and extend radical species lifetime in substrate processing systems. Radical species can be generated during a process (e.g., a plasma-based process). In some embodiments, the process is a clean process. In some embodiments, the process is an etch process.

In some embodiments, a protective coating can be formed on at least one component of a substrate processing system to minimize radical species recombination and extend radical species lifetime. In some embodiments, the at least one component includes at least one of: a processing chamber wall, a gas distribution assembly of a processing chamber, the plasma source (e.g., RPS), or one or more components connected to the plasma source. For example, if the plasma source is an RPS, then the one or more components connected to the plasma source can include one or more delivery lines connecting the RPS to the processing chamber. A protective coating described herein can include a material having a low coefficient of fraction (e.g., nonstick) and having a suitably high surface energy to prevent chemical reaction of radical species (e.g., high energy plasma radicals) with the protective coating and/or other radical species generated during the process. For example, if radical species is more like to slide parallel to the surface of the protective coating, then they are less likely to adhere to the surface of the protective coating and recombine with another radical species. Additionally, the protective coating can reduce the availability of surface recombination sites for radical species to prevent recombination of the radical species. For example, the protective coating can include a molecule having strong cohesive bonds due to pairings between highly electronegative atoms, which makes the protective coating chemically inert. Moreover, the material of the protective coating can be selected to obviate or reduce conditioning of the surface of a component, which can typically be performed to reduce radical recombination. In some embodiments, the protective coating includes a material with a sufficiently high electronegative nature that prevents radical species from reacting with the protective coating, and thus the surface of the at least one component on which the protective coating is formed. Additionally, by using the protective coating, conditioning of the surface of the at least one component may not be performed. In some embodiments, the radical species includes a fluorine radical. In some embodiments, the protective coating includes fluorinated magnesium (Mg). For example, the protective coating can include magnesium fluoride (MgF₂).

Embodiments described herein can provide various technical benefits. For example, embodiments described herein can be used to minimize radical recombination and extend the lifetime of radicals generated during a plasma-based process (e.g., clean process, etch process, etc.). By doing so, embodiments described herein can increase, for example, etch rate of clean processes, which can reduce clean time and therefore increase processing chamber throughput. Embodiments described herein can reduce process costs. For example, the protective coating can be used to decrease radical recombination on surfaces, which can lead to decreased process gas consumption. As another example, since decreasing gas flow can decrease power requirements for generating plasma used to generate radical species during a process (e.g., clean process), the protective coating can be used to decrease the amount of power at which radical species are generated. These and other embodiments, along with many of their advantages and features, are described in more detail in conjunction with the below description and attached figures.

Although the remaining disclosure will routinely identify specific deposition and/or etch processes utilizing the disclosed technology, it will be readily understood that the systems and methods are equally applicable to other deposition, etch, and cleaning chambers, as well as processes as may occur in the described chambers. Accordingly, the technology should not be considered to be so limited as for use with these specific deposition processes or chambers alone. The disclosure will discuss one possible system and chamber that may include lid stack components according to embodiments of the present technology before additional variations and adjustments to this system according to embodiments of the present technology are described.

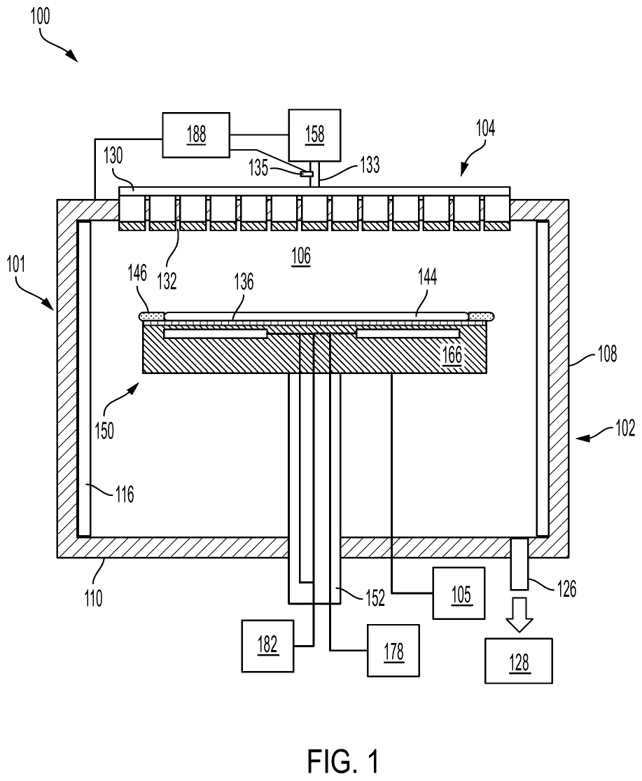

FIG. 1 is a sectional view of a manufacturing system 100 that performs plasma-based processes, according to some embodiments. The manufacturing system 100 may include a processing chamber 101 coupled to a plasma source 158 via one or more gas delivery lines 133. The processing chamber 101 may be, for example, a plasma etch reactor, a deposition chamber, etc. The processing chamber may be suitable for an etching operation, a deposition operation, a chamber cleaning operation, a plasma treatment operation, or any other type of operation typical of a semiconductor manufacturing facility. In an embodiment, one or more substrates (e.g., wafers) 144 may be provided within the processing chamber 101. In an embodiment, processing chamber 101 may be maintained at a pressure suitable for the target operation. In a particular embodiment, the pressure may be between approximately a fraction of a Torr and approximately 200 Torr.

The processing chamber 101 and/or plasma source 158 may be connected to a controller 188, which may control processing of the plasma source 158 and/or processing chamber 101 (e.g., by controlling set points, loading recipes, and so on).

In some embodiments, the plasma source 158 is an RPS that generates plasma at a remote location and delivers the externally generated plasma to the processing chamber 101. Alternatively, the processing chamber 101 may include an integrated plasma source (not shown) that can generate plasma within the processing chamber. In embodiments, the plasma source 158 includes a chamber in which plasma is generated. In embodiments, walls of the chamber for the plasma source 158 are coated with a coating the mitigates radical recombination. In some embodiments, the walls of the plasma source's 158 chamber are coated with magnesium fluoride.

Plasma source 158 is a device that generates and sustains a high-temperature, electrically charged state of matter called plasma. Generated plasma may include ionized gas particles that can conduct electricity and exhibit unique properties. Plasma source 158 may include a gas supply, a chamber, and an energy input. The plasma source 158 may begin with a supply of one or more gases from the gas supply. The one or more gases can include one or more halogen-containing gases. For example, the one or more halogen-containing gases can include one or more fluorine-containing gases to generate plasma containing fluorine radicals, one or more chlorine-containing gases to generate plasma containing chlorine radicals, one or more bromine-containing gases to generate plasma containing bromine radicals, etc. Examples of fluorine-containing gases include fluorine gas (F₂), tetrafluoromethane (CF₄), hexafluoroethane (C₂F₆), sulfur hexafluoride (SF₆), nitrogen trifluoride (NF₃), trifluoromethane (CHF₃), difluoromethane (CH₂F₂), silicon tetrafluoride (SiF₄), etc. Examples of chlorine-containing gases include chlorine gas (Cl₂) and silicon tetrachloride (SiCl₄). An example of a bromine-containing gas is hydrogen bromide (HBr). The one or more gases can further include one or more inert gases. Examples of inert gases include argon (Ar), nitrogen (N₂) helium (He), etc.

This gas serves as a medium that will be ionized to create the plasma. The gas gets introduced into the chamber of the plasma source, where the plasma will be generated. This chamber is typically designed to withstand high temperatures and maintain a controlled environment. In embodiments, regions of the chamber that will be exposed to a generated plasma are coated with a protective coating that mitigates fluorine radical recombination. In some embodiments, the protective coating comprises fluorinated Mg (e.g., MgF₂). The energy input provides energy to the gases within the chamber to create the plasma. The energy input may provide radiofrequency (RF) energy (e.g., for capacitively coupled plasma (CCP) sources and inductively coupled plasma (ICP) sources), microwave energy, an electric arc, and/or a laser-based energy. The provided energy to the gases causes ionization and plasma formation. The energy input causes the gas atoms or molecules to become ionized, meaning they lose or gain electrons and become charged ions. This process involves raising the energy levels of the gas particles, causing them to break apart into ions and free electrons. Once a sufficient number of ions and free electrons are present, the gas transforms into a plasma state. In this state, the ions and electrons coexist, and the plasma exhibits unique properties, such as conductivity and the ability to emit light. Plasma source 158 may employ various systems to contain and control the plasma. This can include systems that generate magnetic fields, systems that generate electric fields, and cooling systems to maintain a target temperature and stability of the plasma.

One or more components of the plasma source 158 may be coated with a protective coating as described above. Examples of such components include one or more electrodes used to generate electric fields, one or more antennas and/or coils used to couple energy into the gases, one or more components of a gas delivery system (e.g., gas inlets, flow controllers, gas delivery lines, etc.), magnetic coils and/or shields (e.g., which may be used to shape and/or stabilize the plasma), windows or viewports, chamber walls, and so on. These components may be formed of a metal (e.g., a metal alloy such as stainless steel or an aluminum alloy) and/or a ceramic.

By coating one or more components of the plasma source 158 with a fluorinated Mg (e.g., MgF₂) coating, an amount of recombination of fluorine radicals in a generated plasma may be mitigated. This reduces an amount of a fluorine-rich gas that may be flowed into the plasma source 158 to generate a target amount of fluorine radicals. Such reduction in the amount of fluorine-rich gases that is used can reduce an environmental impact of plasma-based processes, reduce a cost of plasma-based processes, and so on.

Processing chamber 101 includes a substrate support assembly 150, according to some embodiments. Substrate support assembly 150 can include a puck 166. The puck 166 may perform chucking operations, e.g., vacuum chucking, electrostatic chucking, etc. Substrate support assembly 150 may further include base plate, cooling plate and/or insulator plate (not shown).

Processing chamber 100 includes chamber body 102 and lid 104 that enclose an interior volume 106. Chamber body 102 may be fabricated from aluminum, stainless steel, or other suitable material. Chamber body 102 generally includes sidewalls 108 and a bottom 110. An outer liner 116 may be disposed adjacent to side walls 108, e.g., to protect chamber body 102. Outer liner 116 may be fabricated and/or coated with a plasma or halogen-containing gas resistant material. Outer liner 116 may be fabricated from or coated with aluminum oxide. Outer liner 116 may be fabricated from or coated with yttria, yttrium alloy, oxides thereof, etc.

Exhaust port 126 may be defined in chamber body 102, and may couple interior volume 106 to a pump system 128. Pump system 128 may include one or more pumps, valves, lines, manifolds, tanks, etc., utilized to evacuate and regulate the pressure of interior volume 106.

Lid 104 may be supported on sidewall 108 of chamber body 102. Lid 104 may be openable, allowing access to interior volume 106. Lid 104 may provide a seal for processing chamber 100 when closed. Plasma source 158 may be coupled to processing chamber 100 to provide process, cleaning, backing, flushing, etc., gases and/or plasmas to interior volume 106 through gas distribution assembly 130. Gas distribution assembly 130 may be integrated with lid 104.

Gas distribution assembly 130 (e.g., showerhead) may include multiple apertures 132 on the downstream surface of gas distribution assembly 130. Apertures 132 may direct gas flow to the surface of substrate 144. In some embodiments, gas distribution assembly may include a nozzle (not pictured) extended through a hold in lid 104. A seal may be made between the nozzle and lid 104. Gas distribution assembly 130 may be fabricated and/or coated by a ceramic material, such as silicon carbide (SiC), yttrium oxide (Y₂O₃), etc., to provide resistance to processing conditions of processing chamber 100.

Substrate support assembly 150 is disposed in interior volume 106 of processing chamber 100 below gas distribution assembly 130. Substrate support assembly 150 holds a substrate 144 during processing. An inner liner (not shown) may be coated on the periphery of substrate support assembly 148. The inner liner 118 may share features (e.g., materials of manufacture, function, etc.) with outer liner 116.

Substrate support assembly 150 may include supporting pedestal 152, insulator plate, base plate, cooling plate, and puck 166. Puck 166 may include electrodes 136 for providing one or more functions. Electrodes 136 may include chucking electrodes (e.g., for securing substrate 144 to an upper surface of puck 166), heating electrodes, RF electrodes for plasma control, etc.

Protective ring 146 may be disposed over a portion of puck 166 at an outer perimeter of puck 166. Puck 166 may be coated with a protective layer (not shown). Protective layer 136 may be a ceramic such as Y₂O₃ (yttria or yttrium oxide), Y₄Al₂O₉ (YAM), Al₂O₃ (alumina), Y₃Al₄O₁₂ (YAG), YAlO₃ (YAP), quartz, SiC (silicon carbide), Si₃N₄ (silicon nitride), Sialon, AlN (aluminum nitride), AlON (aluminum oxynitride), TiO₂ (titania), ZrO₂ (zirconia), TiC (titanium carbide), ZrC (zirconium carbide), TiN (titanium nitride), TiCN (titanium carbon nitride), Y₂O₃ stabilized ZrO₂ (YSZ), and so on. The protective layer may be a ceramic composite such as YAG distributed in an alumina matrix, a yttria-zirconia solid solution, a silicon carbide-silicon nitride solid solution, or the like. The protective layer may be sapphire or MgAlON.

Puck 166 may further include multiple gas passages such as grooves, mesas, and other features that may be formed in an upper surface of puck 166. Gas passages may be fluidly coupled to a gas source 105. Gas from gas source 105 may be utilized as a heat transfer or backside gas, may be utilized for control of one or more lift pins of puck 166, etc. Multiple gas sources may be utilized (not shown). Gas passages may provide a gas flow path for a backside gas such as He via holes drilled in puck 166. Backside gas may be provided at a controlled pressure into gas passages to enhance heat transfer between puck 166 and substrate 144.

Puck 166 may include one or more clamping electrodes. The clamping electrodes may be controlled by chucking power source 182. Clamping electrodes may further couple to one or more RF power sources through a matching circuit for maintaining a plasma formed from process and/or other gases within processing chamber 100. The RF power sources may be capable of producing an RF signal having a frequency from about 50 kHz to about 3 gigahertz (GHz) and a power of up to about 10,000 Watts. Heating electrodes of puck 166 may be coupled to heater power source 178.

Process control of radical species is difficult. Particularly, it may not be possible to effectively measure radical species concentration in a chamber. This is due, in part, to the highly reactive nature of the radical species. Radical species can react whenever the radical species contacts any surface or other compound. Even if the surface does not react with the radical species, it still may serve as a site for recombination of the radical species with each other thus converting the species to other useless compounds. As such, some mass spectrometry tools may not be able to measure the concentration of radical species. Without the ability to quantitatively measure the radical species concentrations, effective process control, such as closed loop control, is not possible in existing electronic device manufacturing tools. Closed loop control refers to the use of measurements as a feedback signal to a controller in order to modify processing conditions in an ongoing process.

In some embodiments, at least one radical sensor device 135 may be connected to the gas delivery line(s) 133 to detect radical species in a gas or plasma delivered by the plasma source 158. Additionally, in some embodiments the gas delivery line(s) 133 may be coated with a fluorinated Mg (e.g., MgF₂) protective coating to mitigate fluorine radical recombination between the plasma source 158 and the processing chamber 104. In some embodiments, the radical sensor device 135 is disposed within or connected to the processing chamber 101 rather than in or connected to the gas delivery lines 133. In an embodiment, the radical sensor device 135 is fluidically coupled to the processing chamber 101 and/or to the gas delivery line(s) 133. For example, a valve may be provided along a tube between the processing chamber 101 and the radical sensor device 135. In an embodiment, the valve is a type of valve that allows for an unobstructed line of sight between the processing chamber 101 and the radical sensor device 135. For example, the valve may be an isolation gate valve. An isolation gate valve may allow for a binary state of operation. That is, the valve may be open (i.e., 1) or closed (i.e., 0). When the valve is open, the line of sight is unobstructed. Alternately, another type of valve such as a needle valve may be used.

The radical sensor device 135 can be designed to measure an amount or concentration of target radical species of a target gas or molecule, which other sensor devices may be incapable of detecting without use of expensive optical equipment such as spectroscopy equipment. For example, target radical species can include fluorine radicals, hydrogen radicals, nitrogen radicals, etc.

For example, the radical sensor device 135 can include a radical sensor in a radical sensor holder. In some embodiments, the radical sensor device 135 is an acoustic resonance radical sensor device, and the radical sensor includes a piezoelectric resonator. The piezoelectric resonator can include a base structure including piezoelectric material, and can resonates at a resonant frequency by applying an alternating current to the base structure. In some embodiments, the piezoelectric material includes a crystal (e.g., an SiO₂ or quartz crystal). In some embodiments, the base structure further includes at least one electrode formed on the piezoelectric material. For example, the at least one electrode can include a front electrode formed on a frontside of the piezoelectric material and/or a back electrode formed on a backside of the piezoelectric material. The frontside can correspond to a flat face of the piezoelectric material, and the backside can correspond to a convex face of the piezoelectric material. The at least one electrode can be formed from any suitable metal. Examples of suitable metals include aluminum (Al), gold (Au), etc. In some embodiments, the piezoelectric resonator is a quartz crystal microbalance (QCM) resonator. A QCM resonator uses a quartz crystal including silicon dioxide (SiO₂) as a piezoelectric material. A QCM resonator can be used to detect changes in the resonance frequency of the quartz crystal, which can be used to measure an amount and/or concentration of radical species.

A specialized chemical filter (“filter”) can be formed on one or more surfaces of the base structure. For example, the filter can be formed on the piezoelectric material. In some embodiments, the filter is formed on an electrode (e.g., the front electrode). The filter can be composed of a material that is reactive to the target radical species, and can be used to filter out all molecules except for the target radical species. The filter can change mass based on the reaction of the filter to the target radical species. The change in the filter's mass can cause the resonant frequency at which the piezoelectric material oscillates to change. This change in the resonant frequency is measurable, and may be used to determine the quantity of the target radical species that reacted with the filter. Accordingly, the radical sensor device 135 can include a filter, disposed on the base structure (e.g., a surface of a piezoelectric material), that is reactive to target radical species, but that is not reactive to stable molecules of the gas or molecule or to radical or stable species of other gases or molecules that are flowed together with the target gas or molecule.

In some embodiments, the filter is formed as coating. For example, the coating can include a film of an amorphous material (e.g., amorphous SiO₂). However, such coatings can degrade relatively quickly over time due to mass reduction caused by radical species (e.g., etching), which may prompt replacement of the radical sensor device 135. Additionally, the degradation can affect the ability of the radical sensor device 135 to perform radical species detection.

To improve the lifespan and performance of the radical sensor device 135, in some embodiments, the filter is an enhanced filter. The enhanced filter can have a more stable reaction and/or a lower rate of reaction with radical species, while still being unreactive to a non-radical species (e.g., a more stable reaction and lower rate of reaction with atomic fluorine (F), while still being unreactive to molecular fluorine (F₂)).

In some embodiments, the enhanced filter is formed on the front electrode of the piezoelectric resonator. In some embodiments, the base structure does not include a front electrode, and the enhanced filter is formed directly on the piezoelectric material. Various methods for forming an enhanced filter are contemplated.

In some embodiments, forming an enhanced filter on the base structure includes forming a crystalline material on the base structure. For example, the crystalline material can be formed on a front electrode of the base structure. In some embodiments, the crystalline material is a monocrystalline material. In some embodiments, the crystalline material is a polycrystalline material. In some embodiments, the crystalline material includes SiO₂.

An interface between the crystalline material and the base structure can be a high quality interface to enable an acoustic wave to travel through the interface. For example, a high quality interface can be an interface having a suitable porosity. In some embodiments, a high quality interface has a porosity of less than or equal to about 20%, a porosity of less than or equal to about 30%, or a porosity of less than or equal to 40%.

In some embodiments, the crystalline material is cut from a base material. For example, the crystalline material can include a SiO₂ crystal (e.g., monocrystalline SiO₂ or polycrystalline SiO₂) cut from a base quartz material. In some embodiments, the crystalline material has a thickness that ranges from about 5 micrometers to about 50 micrometers.

In some embodiments, forming the crystalline material on the base structure includes attaching the crystalline material to base structure (e.g., the front electrode). For example, forming the crystalline material on the base structure can include using a sintering process to attach the crystalline material to a surface of the base structure (e.g., a surface of the front electrode). As another example, forming the crystalline material on the base structure can include using an anneal process to attach the crystalline material to a surface of the base structure (e.g., a surface of the front electrode). As yet another example, forming the crystalline material on the base structure can include using a bonding layer (e.g., glue) to attach the crystalline material to a surface of the base structure (e.g., a surface of the front electrode). The bonding layer can have suitable properties to enable an acoustic wave to penetrate through an interface. In some embodiments, the bonding layer improves an interface between the crystalline material and the base structure (e.g., reduces a porosity at the interface between the crystalline material and the base structure, such as by flowing to fill pores or voids at the interface).

In some embodiments, forming the crystalline material on the base structure includes etching the crystalline material from the piezoelectric material. More specifically, the base structure can lack a front electrode, and a mesh can be formed directly on a surface of the piezoelectric material. In some embodiments, forming the mesh includes placing the mesh on the surface of the piezoelectric material. In some embodiments, forming the mesh includes depositing the mesh on the surface of the piezoelectric material. The mesh can include any suitable material in accordance with embodiments described herein. Examples of suitable materials include Al, Au, nickel (Ni), etc. After the mesh is formed, radical species can then be used to etch the piezoelectric material in a pattern defined by the mesh. In such embodiments, the front surface of the piezoelectric material of the base structure itself acts as the filter, and so the base structure may be composed of a material that is selectively reactive to target radical species. In some embodiments, the base structure is or includes SiO₂.

In some embodiments, a filter includes a crystal structure having a number of grains. A grain can refer to a crystal having a particular orientation. A crystal structure (e.g., polycrystalline material) can include multiple grains each having a respective orientation (e.g., random orientation) within the crystal structure. A pair of grains of a crystal structure can be separated by an interface referred to as a grain boundary. In some embodiments, a grain has a microstructure grain size selected to achieve a target filter lifetime depending on process conditions within which the radical sensor device 135 operates. In some embodiments, the microstructure grain size ranges between about 100 nanometers to about 50 micrometers, such as 200 nanometers, 300 nanometer, 400 nanometer, 500 nanometers, 1 micrometer, 5 micrometers, 10 micrometers, 25 micrometers, and so on. Additionally, increasing grain boundary size can increase the activation energy needed to induce a chemical reaction. Therefore, increasing grain boundary size can result in a greater amount or concentration of radical species being accumulated before etching of the material of the filter occurs.

In some embodiments, forming an enhanced filter on the base structure includes forming an enhanced coating on the base structure. For example, the enhanced coating can be formed on a front electrode of the base structure.

In some embodiments, forming the enhanced coating on the base structure includes forming a coating on the base structure using a high temperature deposition process. In contrast to deposition processes that performs an initial low temperature or “cold” deposition of material, a high temperature deposition process maintains a high temperature throughout the entire process. An enhanced coating formed using a high temperature deposition process can exhibit decreased etch rates when exposed to radical species as compared to a coating formed using other deposition processes. In some embodiments, the high temperature deposition process is performed at a temperature that ranges from about 150° C. to about 450° C., such as 200° C., 250° C., 300° C., 350° C., or 400° C. Examples of deposition processes that can be used to perform a high temperature deposition process include physical vapor deposition (PVD) (e.g., magnetron sputtering or electron beam evaporation), atomic layer deposition (ALD), chemical vapor deposition (CVD), plasma spray, ion assisted deposition (IAD), electron beam IAD (EB-IAD), etc. In some embodiments, a deposition process is a thin-film deposition process.

For example, the deposition process can be electron beam evaporation. Electron beam evaporation is a type of PVD process. During electron beam evaporation, a target material (e.g., anode) is bombarded with an electron beam. The electron beam can be generated from a filament (e.g., tungsten filament) and steered by electric and magnetic fields to strike the target material. The electron beam causes atoms from the target material to transform into a gaseous phase. These atoms can then precipitate into solid form, coating surfaces with a layer of the target material. Electron beam evaporation can occur under high vacuum conditions to avoid contamination. In some embodiments, the deposition process is ion-assisted electron beam evaporation. During ion-assisted electron beam evaporation, an ion beam including ions (e.g., argon ions) with various energies can be directed to a target substrate along with the target material. The ion beam can impart energy into the gaseous phase atoms to improve properties of the layer of the target material (e.g., adhesion, density and/or grain structure).

In some embodiments, forming the enhanced coating on the base structure includes forming a thick coating on the base structure using a deposition process. In some embodiments, the deposition process is a high temperature deposition process, as described above. A thicker coating can increase the lifespan of the piezoelectric resonator. However, too thick of a coating can have a negative impact on performance of the piezoelectric resonator by blocking the transmission of acoustic waves. Thus, the thickness of the coating can be optimized to balance piezoelectric resonator lifespan with piezoelectric resonator performance. In some embodiments, the thick coating has a thickness that ranges between about 5 micrometers to about 50 micrometers, such as 10 micrometers, 15 micrometers, 20 micrometers, 25 micrometers, 30 micrometers, 35 micrometers, 40 micrometers, or 45 micrometers.

In some embodiments, forming the enhanced coating on the base structure includes forming an initial coating on the base structure using a deposition process (e.g., PVD, ALD or CVD), and doping the initial coating to obtain the enhanced coating. In some embodiments, the deposition process is a high temperature deposition process, as described above. Any suitable doping process can be used to dope the initial coating to obtain the enhanced coating. Examples of doping processes include particle bombardment (e.g., helium (He) bombardment), particle implantation (e.g., ion implantation), etc. Examples of dopants that can be used to dope the initial coating include yttrium (Y), phosphorous (P), boron (B), etc. In some embodiments, the dopant is deposited at the same time as a base material (e.g., base coating).

In some embodiments, a filter includes a material that increases radical species detection resolution and measurement accuracy in the radical sensor device 135 by reducing sensor signal noise. Such a material can increase the radical detection rate of the filter to the radical species. The thickness range of the material can vary between 500 nanometers to about 50 micrometers. The diameter of the material can range between about 2 millimeters to about 14 millimeters. For example, in the context of fluorine radical detection, the material can include FC212 silicon.

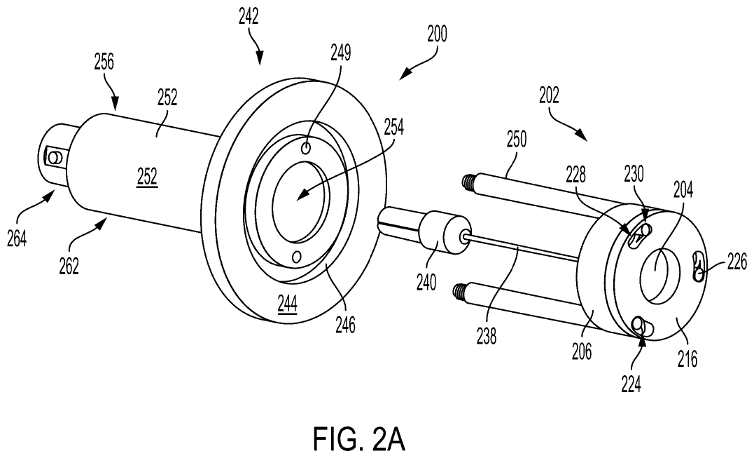

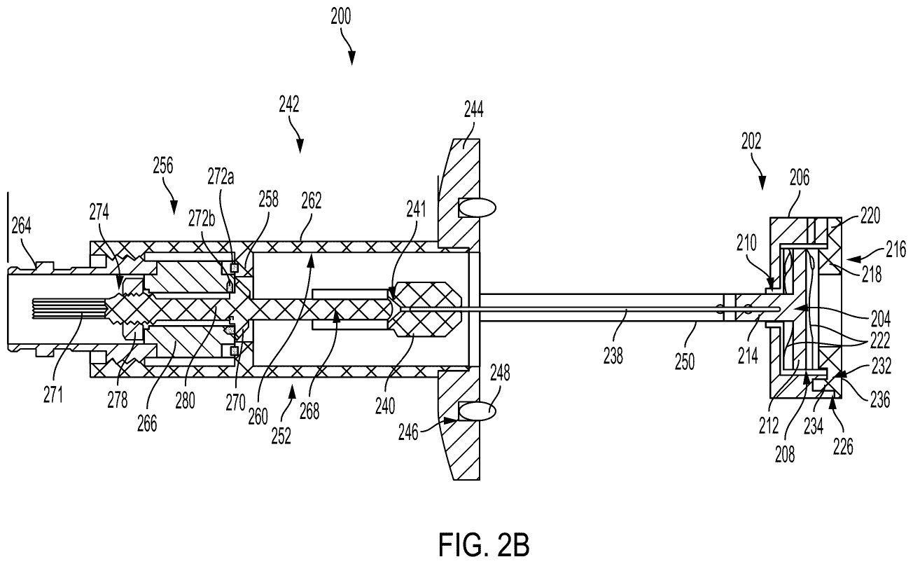

The radical sensor device 135 can be used to measure thickness change of the filter formed on the base structure. Thickness change expressed in terms of areal mass density (mass per unit area) may be more appropriate at subatomic sizes. For heavy loading on the base structure, accuracy of the measurement can depend on the knowledge of the shear-mode acoustic impedance value of the deposited material. Larger crystals do not have higher sensitivity. Since the radical sensor device 135 is not a weighing device as it does not require a gravitational force, the radical sensor device 135 can be used in zero gravity environments such as outer space. In some embodiments, a thickness reading of the filter, t_{f}, may be derived from the areal mass density value of the filter based on the density of the material, ρ_{f} (e.g., t_{f}ρ_{f}). The areal mass density measurement is in absolute value, in some embodiments. In some embodiments, no calibration is needed for a properly designed radical sensor. Temperature variation, stress, gas adsorption and desorption, surface reaction, etc. can all give false signals. The radical sensor device 135 is described in greater detail below with reference to FIGS. 2-6.

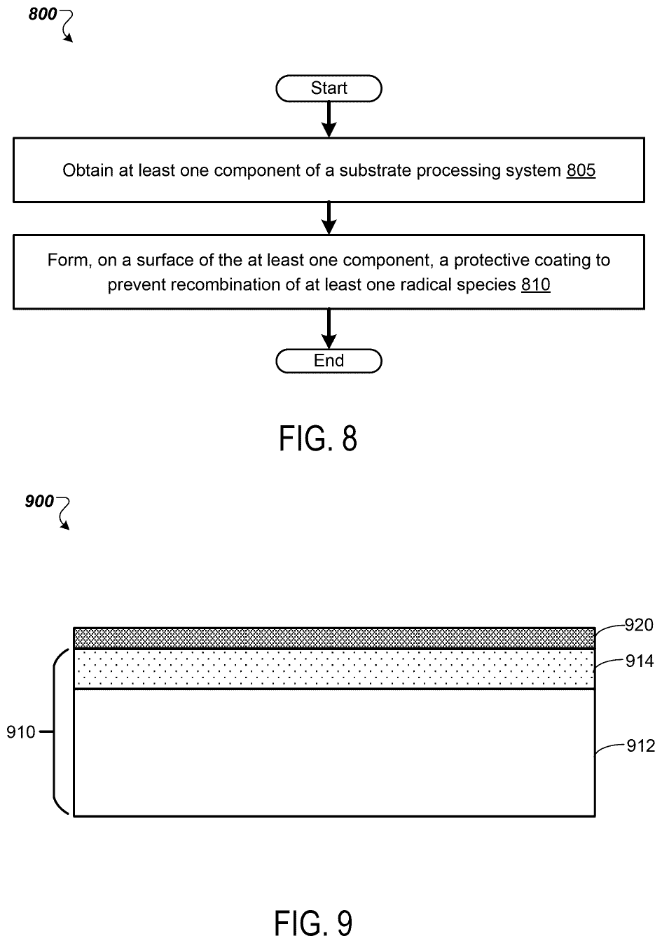

System controller 188 may control one or more parameters and/or set points of the plasma source 158 and/or processing chamber 101. System controller 188 can be and/or include a computing device such as a personal computer, a server computer, a programmable logic controller (PLC), a microcontroller, and so on. System controller 188 can include one or more processing devices, which can be general-purpose processing devices such as a microprocessor, central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets or processors implementing a combination of instruction sets. The processing device can also be one or more special-purpose processing devices such as an application specific integrated circuit (ASIC), a field programmable gate array (FPGA), a digital signal processor (DSP), network processor, or the like. System controller 188 can include a data storage device (e.g., one or more disk drives and/or solid state drives), a main memory, a static memory, a network interface, and/or other components. System controller 188 can execute instructions to perform any one or more of the methodologies and/or embodiments described herein (e.g., one or more of the methods described below with reference to FIGS. 8 and 10-11. The instructions can be stored on a computer readable storage medium, which can include the main memory, static memory, secondary storage and/or processing device (during execution of the instructions). For example, system controller 188 may receive measurements from the radical sensor device 135 indicating an amount or concentration of a particular radical species, and may adjust one or more properties or settings (e.g., such as a plasma power) of the plasma source 158 responsive to the measured radical concentration (e.g., closed loop control). For example, the radical sensor device 135 can measure the amount and/or concentration of the radical species to obtain a measured value, and the system controller 188 can compare the measured value to a setpoint value. When the measured value is below the setpoint value, the system controller 188 can cause processing parameters to be changed increase the generation rate and output concentration of the radical species. Alternatively, when the measured value is above the setpoint value, the system controller 188 can cause processing parameters to be changed to decrease the concentration of the radical species. As such, the radical sensor device 135 can be used to implement more stable and reproducible processes. The system controller 188 can also be configured to permit entry and display of data, operating commands, and the like by a human operator.

The piezoelectric resonator of the radical sensor device 135 can be designed for a specific application, and the filter of the radical sensor device 135 can include a material reactive to only selected molecular gas species used in the specific application. Examples of specific applications include etch operations, plasma assisted deposition processes (e.g., plasma assisted atomic layer deposition), etc. In an example, for a fluorine-based etch process, an etch rate may strongly correlate to a concentration of fluorine radicals. Without the use of a radical sensor device including a suitable piezoelectric resonator (e.g., QCM resonator), the concentration of fluorine radicals may not be directly detectable, and so engineers would guess at the concentration of fluorine radicals based on other known values such as a known plasma power, a known gas flow rate, and so on. By using the radical sensor device 135, the amount or concentration of fluorine radicals being flowed may be directly measured, and this measurement may be used by the system controller 188 to finely control the amount or concentration of radical species being generated and output by the plasma source 158.

FIGS. 2A-2B illustrate an example radical sensor device 200, in accordance with some embodiments. Radical sensor device 200 may can be disposed within a processing region of a deposition, etch, and/or other type of processing chamber, such as processing chamber 101 of manufacturing system 100 of FIG. 1.

Radical sensor device 200 may include radical sensor holder 202, which may be sized and shaped to receive radical sensor 204. In some embodiments, radical sensor device 200 is an acoustic resonance sensor device. In some embodiments, radical sensor 204 includes a piezoelectric resonator. For example, radical sensor 204 can include a QCM resonator.

For example, shown in FIG. 2B, radical sensor holder 202 may include body 206 that defines recess 208 and aperture 210. Radical sensor 204 may include disc body 212 and may include stem 214 extending from disc body 212. Disc body 212 may be circular or otherwise round in some embodiments, although other shapes are possible. Disc body 212 may be seated within recess 208, while stem 214 may extend through aperture 210. In some embodiments, electrically conductive resilient members 222 (such as springs) may be positioned above and/or below disc body 212 to help maintain electrical contact between radical sensor 204 and radical sensor holder 202, while ensuring that pressure between lid 216 and body 206 does not crack or otherwise damage radical sensor 204. In some embodiments, resilient members 222 may be formed from and/or coated with chamber-compatible materials to ensure that resilient members 222 do not corrode during exposure to process gases and plasmradical species. In some embodiments, resilient members 222 may be formed from and/or coated with a corrosion-resistant material. For example, resilient members 222 can be formed from palladium (Pd), although other materials may be used in various embodiments.

Lid 216 may be coupled with body 206 to secure radical sensor 204 within recess 208. Lid 216 may include inner portion 218 that may extend into recess 208 and may press against radical sensor 204 and/or resilient member 222 that may be disposed between lid 216 and radical sensor 204. Lid 216 may also include flange 220 that is coupled with inner portion 218. Flange 220 may be positioned against an upper surface of body 206. Flange 220 may include slots 224 that may receive fasteners 226 that secure lid 216 to body 206. In some embodiments, fasteners 226 may be screws, however when body 206 is formed from aluminum alloys, screws may be undesirable due to the nature of aluminum threads to wear over time. In such embodiments, other fasteners, such as press-fit connections, may be utilized. For example, each slot 224 may be generally arcuate in shape and may be keyed. In the present embodiment, each slot 224 may include receiving end 228 and locking end 230. Receiving end 228 may be wider than locking end 230. For example, medial and/or bottom portion of each slot may taper to a narrower width along a length of each slot 224 to form locking end 230 having a shelf 232. In some embodiments, an upper portion of each slot 224 may have a constant width. Fasteners 226 may each be a pin having an elongate pin body 234 that couples with pin head 236 having a greater diameter than pin body 234. Each pin body 234 may be secured within body 206, such as by being press fit within a recess formed within body 206, with each respective pin head 236 extending above and being spaced apart from an upper surface of body 206. Lid 216 may be positioned atop body 206 with each pin head 236 extending through receiving end 228 of respective slot 224. Lid 216 may then be rotated relative to body 206 to slide each pin head 236 toward and into engagement with locking end 230 of each slot 224 to secure lid 216 against body 206. In such a position, a bottom surface of each pin head 236 may be seated against shelf 232, which prevents lid 216 from being pulled away from body 206 until rotated in the opposite direction to align each pin head 236 with receiving end 228 of respective slot 224. Such a configuration may enable lid 216 to be repeatedly removed from and resecured to body 206 to insert and/or remove Radical sensor 204 from recess 208.

Radical sensor 204 may be formed from a crystalline material, such as a polycrystalline material that may react with radical species (e.g., plasmradical species). In embodiments, radical sensor 204 includes any of the improved filters described herein, where the filter is configured to react with the radical species. The reaction with the radical species may result in the additional or removal of a small amount of mass of the crystalline material and/or filter, such as due to oxide growth/decay and/or a film deposition on the surface of radical sensor 204. The mass change may alter the frequency of radical sensor 204. The frequency may be measured and correlated to plasma radical concentration values, which may enable radical sensor 204 to be effectively used to monitor (e.g., detect and/or measure) radical species within the processing region of a processing chamber. Radical sensor 204 may be formed from various quartz crystals, such as, but not limited to, SiOₓ.

Radical sensor holder 202 may be formed from an electrically conductive and/or chamber compatible material. In some embodiments, all of radical sensor holder 202 may be formed from or coated with an electrically conductive chamber compatible material. In some embodiments, radical sensor holder 202 includes Al. For example, radical sensor holder 202 can include an Al alloy. In some embodiments, an Al alloy includes magnesium, such as between 5% and 20% by mass of magnesium, which may provide enhanced corrosion resistance (e.g., when fluorinated during processing operations). In some embodiments, aluminum 5083 and/or aluminum 6061 may be used, although other aluminum alloys may be utilized in various embodiments. The use of aluminum may also provide a large surface area of thermally conductive material in contact with radical sensor 204 and thereby reduce acoustic resonance shifts due to thermal affects.

Radical sensor device 200 may include electrical transmission line 238 that may be electrically coupled with radical sensor 204. For example, stem 214 may define a recess 241 that may receive an end of electrical transmission line 238. In some embodiments, the end of electrical transmission line 238 may be secured within stem 214 using a set screw, however other securement techniques are possible in various embodiments. An opposite end of electrical transmission line 238 may be secured within a first end of an adapter 240, such as by using an additional set screw to secure the opposite end of electrical transmission line 238 into a recess formed in the first end of adapter 240.

Radical sensor holder 202 and at least a portion of electrical transmission line 238 may be designed to be exposed to the processing region of a processing chamber. To help mount holder within the processing chamber, radical sensor device 200 may include an exterior portion 242, which may be positioned outside of the processing region. For example, exterior portion 242 may be disposed against an outer wall of a chamber body, liner assembly, and/or other component of the processing chamber that defines a portion of the processing region. The component may define a small aperture through which radical sensor holder 202 may be inserted. Exterior portion 242 may include flange 244 having a greater diameter than radical sensor holder 202. Flange 244 may be positioned against an outer surface of the chamber component defining the aperture, and may prevent the remaining parts of exterior portion 242 from being inserted within the processing chamber. Flange 244 may define annular recess 246. Annular sealing member 248 may be seated within annular recess 246 and may be used to provide a vacuum seal for an interface between flange 244 and a chamber component that flange 244 is positioned against. Flange 244 may define a number of connectors 249, such as threaded connectors. Each connector 249 may receive an end of a respective one of standoffs 250. Standoffs 250 may extend between and couple radical sensor holder 202 and flange 244. Standoffs 250 may be removably coupled with flange 244 and/or radical sensor holder 202, such as via threaded connections. In some embodiments, ends of each standoff of standoffs 250 may be permanently coupled with one of radical sensor holder 202 or flange 244. Connectors 249 and standoffs 250 may be disposed radially inward of annular recess 246, which may ensure that annular sealing member 248 is able to seal an area radially outward of connectors 249 and standoffs 250.

Exterior portion 242 may include connector 256 having housing 252 that extends from flange 244 in a direction opposite radical sensor holder 202. Housing 252 and flange 244 may collectively define central aperture 254 that extends through an entire length of exterior portion 242. Housing 252 may include housing shoulder 258 that extends radially inward from an inner sidewall 260 of housing 252. Housing shoulder 258 may define a portion of central aperture 256, with the portion of central aperture 256 that passes through housing shoulder 258 having a smaller diameter than the rest of central aperture 256. In some embodiments, housing 252 may include first housing portion 262 and second housing portion 264 that are coupled together, either permanently or reversibly (e.g., using a threaded connection). For example, first housing portion 262 may extend from flange 244 and may define housing shoulder 258. Second housing portion 264 may be coupled with a distal end of first housing portion 262 and may define a coupling mechanism for coupling radical sensor device 200 with a coupling mechanism of an electrical port, such as a Bayonet Neill-Concelman (BNC) connection. First housing portion 262 and second housing portion 264 may be reversibly coupled with one another to enable interior components, such as isolator 266, to be inserted and secured within an interior of housing 252.

Adapter 240 and one end of electrical transmission line 238 may be disposed within central aperture 256. A second end of adapter 240 may define an additional recess that may receive a first end of electrical connection 268. A second end of electrical connection 268 may include a connection member 271, such as a BNC bayonet that may be inserted within a corresponding electrical port of a processing chamber. Electrical connection 268 and electrical transmission line 238 may be used to electrically couple radical sensor 204 with the chamber electrical port for transmission of electrical signals between radical sensor 204 and chamber electronics. In some embodiments, a medial portion of electrical connection 268 may include flange 270 that extends radially outward from a body of electrical connection 268. Flange 270 may be positioned in alignment or a slight offset with housing shoulder 258. Isolator 266 may define an aperture 273 through which a portion of electrical connection 268 may pass. A first end of isolator 266 may be seated against a rear surface of housing shoulder 258 and a rear surface of flange 270. In some embodiments, the first end of isolator 266 may be a single planar surface, such as when rear surfaces of housing shoulder 258 and flange 270 are in substantial alignment. In other embodiments, the first end of isolator 266 may include a stepped interface, such that an outer portion of the first end protrudes beyond an inner portion of the first end. Such a configuration may enable an offset between rear surfaces of housing shoulder 258 and flange 270. Scaling members 272 may be disposed between the first end of isolator 266 and rear surfaces of each of housing shoulder 258 and flange 270. For example, first sealing member 272a may be disposed between the first end of isolator 266 and a rear surface of housing shoulder 258 and second sealing member 272b may be disposed between the first end of isolator 266 and a rear surface of flange 270. In some embodiments, each sealing member 272 may be an O-ring, gasket, or other compressible sealing element. Each sealing member 272 can be formed from an elastomeric polymer and/or chamber-compatible material.

Compression of sealing members 272 may provide a vacuum seal within the interior of central aperture 254 and may enable radical sensor holder 202 to be positioned within a low pressure/vacuum environment while exterior portion 242 remains at higher (e.g., atmospheric) pressures. To ensure that sealing members 272 are sufficiently compressed, radical sensor device 200 may include an adjustment mechanism that enables an amount of compressive force applied to sealing members 272 to be controlled. In the illustrated embodiment, the adjustment mechanism may include threads 274 formed on shaft 280 of electrical connection 268. Nut 278 may be threadingly engaged with threads 274 such that as nut 278 is tightened, nut 278 moves toward and contacts a second end of isolator to force isolator 266 toward flange 270, housing shoulder 258, flange 244, and radical sensor holder 202. Movement of isolator 266 in this direction causes sealing members 272 to be compressed to create a vacuum seal between isolator 266, housing 252, and electrical connection 268. In some embodiments, nut 278 may be secured to threads 274 and tightened prior to coupling second housing portion 264 with first housing portion 262, which may provide additional clearance for a wrench or other tool to manipulate nut 278. Once nut 278 is tightened, second housing portion 264 may be secured to first housing portion 262, such as by engaging threaded connectors of each housing portion. In some embodiments, a proximal/inner end of second housing portion 264 may be disposed within central aperture 254 and may contact the second end of isolator 266. In some embodiments, the second end of isolator 266 may be a single planar surface such that when nut 278 and second housing portion 264 are tightened, nut 278 and second housing portion 264 are in substantial alignment. In other embodiments, the second end of isolator 266 may include a stepped interface, such that an inner portion of the second end protrudes beyond an outer portion of the second end. Such a configuration may accommodate an offset between surfaces nut 278 and second housing portion 264.

Isolator 266 may be formed from an electrically insulting material, such as a dielectric or ceramic material (e.g., alumina). Such materials may ensure that isolator 266 may support electrical connection 268 within a center of central aperture 254 while insulating housing 252 from electrical connection 268 to ensure that there is no shorting or transmission of electrical signals between electrical connection 268 and housing 252. Other than isolator 266, exterior portion 242 may be formed from and/or coated with a chamber compatible material, such as an aluminum alloy, as portions of the interior of exterior portion that are between sealing members 272 and flange 244 may be exposed to process gases, radical species, and/or low pressure environments. In some embodiments, some or all of exterior portion 242 (aside from isolator 266) may be formed from and/or coated with a same material as radical sensor holder 202, although other materials are possible in various embodiments.

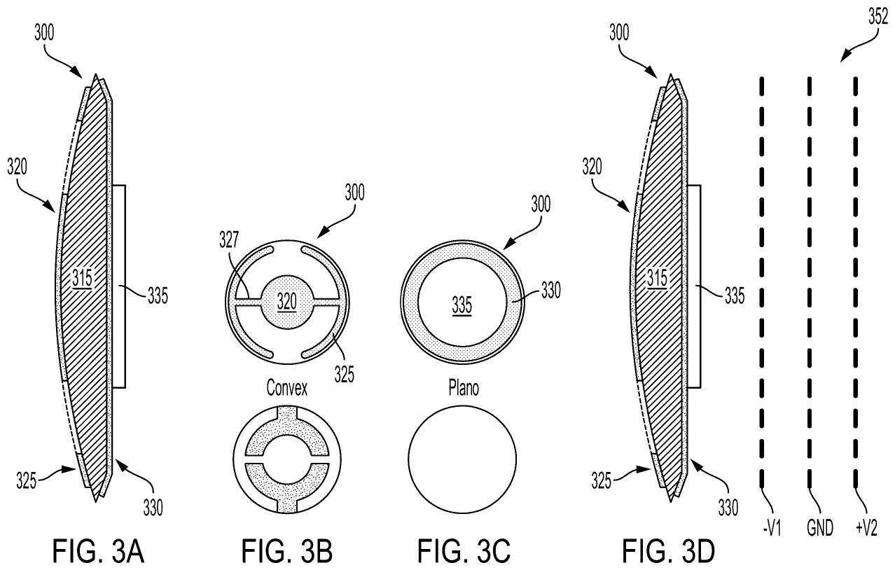

FIGS. 3A-3D illustrate an example radical sensor 300 of a radical sensor device, in accordance with embodiments of the present disclosure. In some embodiments, radical sensor 300 corresponds to radical sensor 204 of FIGS. 2A-2B. FIG. 3A is a sectional side view of radical sensor 300, according to some embodiments. FIG. 3B is a back view of radical sensor 300 of FIG. 3A, according to some embodiments. FIG. 3C is a front view of radical sensor 300 of FIG. 3A, according to some embodiments.

In some embodiments, radical sensor 300 includes a piezoelectric resonator. For example, radical sensor 300 can include a QCM resonator. As shown, radical sensor 300 can include a base structure including radical sensor base 315. In some embodiments, radical sensor 300 includes a piezoelectric resonator and radical sensor base 315 includes a piezoelectric material that can oscillate at certain resonant frequencies. Radical sensor base 315 may include a thin plate of a piezoelectric crystal (e.g., quartz crystal) that oscillates in the thickness-shear mode because such radical sensor base 315 has high sensitivity to mass change on the crystal. The piezoelectric nature of the crystal allows the crystal to be driven into oscillation and with its resonant frequency measured by simple electrical means. In some embodiments, the crystal is precisely cut at certain angles with respect to its crystallographic axes. By increasing the mass of the vibrating unit, the typical result is the decrease of that solid material's resonant frequencies.

As shown in FIGS. 3A-C, radical sensor base 315 can have a flat face and a convex face. The flat face may be a front face and the convex face may be a back face. As shown, the base structure can further include back electrode 320 and front electrode 330. For example, in this example, the flat face may be covered by front electrode 330 and the convex face may be covered by back electrode 320. In some embodiments, back electrode 320 includes back electrode edge 325 connected to back electrode center 320 via one or more electrode bridges 327. This configuration enables an alternating current to be applied to and/or read from the electrodes without compromising the ability of quartz body 315 to oscillate freely. A sensing surface of radical sensor 300 may be a center region of the front face (e.g., a center region of front electrode 330). In some embodiments, the sensing surface of radical sensor 300 is coated with filter 335 that is sensitive to reaction with a particular molecular species of a target gas species. The composition of filter 335 may depend on the application for which radical sensor 300 will be used. In some embodiments, filter 335 includes a coating (e.g., film).

In some embodiments, filter 335 is composed of a material that reacts with a radical molecular species of a target gas, but that does not react to stable molecular species of the target gas. For example, the material of filter 335 may react to fluorine radicals, but may not react to stable molecules containing fluorine, such as F₂, C₂F₆, SF₆, NF₃, CF₄, CHF₃, CH₂F₂, etc. The material of filter 335 may also not react to other molecules that may be included in a gas flow, whether those other molecules are radical species or stable molecular species. For example, the material of filter 335 may react to fluorine radicals, but may not react to carbon radicals, nitrogen radicals, hydrogen radicals, etc. Alternatively, the material may only react to hydrogen radicals, or may only react to carbon radicals, or may only react to some other radical species.

In some embodiments in which the radical sensor is tuned to detect fluorine radicals, filter 335 includes silicon dioxide (SiO₂), tungsten, or a tungsten oxide (e.g., tungsten (III) oxide or W₂O₃) and/or organic materials (such as photoresist). In some embodiments in which the radical sensor is tuned to detect fluorine radicals, the filter 335 includes a transition metal that selectively reacts with fluorine radicals. In some embodiments in which the radical sensor is tuned to detect hydrogen radical species, filter 335 includes a polymer of carbon and hydrogen. One example of a polymer that may be used is polymethyl methacrylate (PMMA). In some embodiments in which the radical sensor is tuned to detect nitrogen radical species, film or coating 335 includes a fluorinated polymer. In some embodiments, the target radical species react with filter 335 to form a gas, which consumes some portion of filter 335. The consumption of some portion of filter 335 reduces the number of molecules of filter 335, and thus reduces an overall mass of the film. This reduction in mass may be detected by radical sensor 300 on which filter 335 has been formed.

In some embodiments, the reaction of the target radical species with filter 335 produces a solid byproduct. The solid byproduct adheres to filter 335, and thus increases a mass of the filter 335. This increase in mass may be detected by radical sensor 300 on which the filter 335 has been formed.

In some embodiments, the reaction of the target radical species with the filter 335 is an absorption process where filter 335 absorbs the target radical species. The absorption of the radical species causes a mass of filter 335 to increase. Once filter 335 becomes saturated with the target radical species and/or between process runs, a purge or cleaning process may be performed to cause the radical species to desorb from filter 335. In an example, a QCM with a coating of PMMA may be used to detect fluorine radicals. The PMMA may absorb fluorine radicals, and the mass change of the film caused by absorption of the fluorine radicals may be detected by a change in resonant frequency of radical sensor 300. The fluorine radicals may then be desorbed by flowing another gas such as argon across radical sensor device 200.

In some embodiments, filter 335 has a thickness of about 1-100 micrometers. In some embodiments, film 235 has a thickness of about 30-40 micrometers. Other thicknesses, such as 10, 20, 30, 40, 50, 60, 70, 80 or 90 micrometers may also be used for film 235.

In some embodiments, filter 335 is a coating. In some embodiments, forming filter 335 includes forming the coating using a high temperature deposition process. A coating formed using a high temperature deposition process can exhibit decreased etch rates when exposed to radical species as compared to a coating formed using other deposition processes. In some embodiments, the high temperature deposition process is performed at a temperature that ranges from about 150° C. to about 450° C. Examples of deposition processes that can be used to perform a high temperature deposition process include PVD (e.g., magnetic sputtering or electron beam evaporation), ALD, CVD, plasma spray, IAD, EB-IAD, etc.

In some embodiments, filter 335 includes a thick coating formed using a deposition process. In some embodiments, the deposition process is a high temperature deposition process, as described above. A thicker coating can increase the lifespan of radical sensor 300. However, too thick of a coating can negative impact performance of radical sensor 300 by blocking the transmission of acoustic waves. Thus, the thickness of the coating can be optimized to balance lifespan with performance. In some embodiments, the coating of filter 335 has a thickness that ranges between about 5 micrometers to about 50 micrometers.

In some embodiments, filter 335 includes a doped coating. For example, forming filter 335 can include forming an initial coating on the base structure using a deposition process (e.g., PVD, ALD or CVD), and doping the initial coating with a dopant to obtain filter 335. In some embodiments, the deposition process is a high temperature deposition process, as described above. Any suitable doping process can be used to dope the initial coating to obtain the enhanced coating. Examples of doping processes include particle bombardment (e.g., He bombardment), particle implantation (e.g., ion implantation), etc. Examples of dopants that can be used to dope the initial coating include Y, P, B, etc. In some embodiments, a base material (e.g., base coating) and the dopant are deposited at substantially the same time to form filter 335.

In some embodiments, filter 335 includes a material that increases radical species detection resolution and measurement accuracy in radical sensor 300 by reducing sensor signal noise. Such a material can increase the radical detection rate of filter 335 to the radical species. The thickness range of the material can vary between 500 nanometers to about 50 micrometers. The diameter of the material can range between about 2 millimeters to about 14 millimeters. For example, in the context of fluorine radical detection, the material can be FC212 silicon.

In some embodiments, filter 335 includes a crystalline material. For example, the crystalline material can be formed on front electrode 330. In some embodiments, the crystalline material is a monocrystalline material. In some embodiments, the crystalline material is a polycrystalline material. In some embodiments, the crystalline material includes SiO₂.

An interface between the crystalline material and the base structure can be a high quality interface to enable an acoustic wave to travel through the interface. For example, a high quality interface can be an interface having a suitable porosity. In some embodiments, a high quality interface has a porosity of less than or equal to about 20%, a porosity of less than or equal to about 30%, or a porosity of less than or equal to 40%.

In some embodiments, the crystalline material is cut from a base material. For example, the crystalline material can include a SiO₂ crystal (e.g., monocrystalline SiO₂ or polycrystalline SiO₂) cut from a base quartz material. In some embodiments, the crystalline material has a thickness that ranges from about 5 micrometers to about 50 micrometers.

In some embodiments, forming the crystalline material on the base structure includes attaching the crystalline material to the base structure (e.g., front electrode 330). For example, forming the crystalline material on the base structure can include using a sintering process to attach the crystalline material to a surface of the base structure (e.g., a surface of front electrode 330). As another example, forming the crystalline material on the base structure can include using an anneal process to attach the crystalline material to a surface of the base structure (e.g., a surface of front electrode 330). As yet another example, forming the crystalline material on the base structure can include using a bonding layer to attach the crystalline material to a surface of the base structure (e.g., a surface of front electrode 330). The bonding layer can have suitable properties to enable an acoustic wave to penetrate through an interface.

In some embodiments, filter 335 includes a crystal structure having a number of grains. In some embodiments, a grain has a microstructure grain size selected to achieve a target filter lifetime depending on process conditions within which the radical sensor operates. In some embodiments, the microstructure grain size ranges between about 100 nanometers to about 50 micrometers. Additionally, increasing grain boundary size can increase the activation energy needed to induce a chemical reaction. Therefore, increasing grain boundary size can result in a greater amount or concentration of radical species being needed before seeing etching of the material of filter 335.

FIG. 3D is a sectional side view of radical sensor 300 with the addition of a charged grating or grid, according to some embodiments. In some embodiments, radical sensor 300 measures radical species without respect to charge. In some embodiments, it may be advantageous to measure only neutral radical species or only radical species having a particular charge. In order to measure only neutral radical species of a particular molecular species, charged grating or grid 352 may be disposed in front of the front face of the radical sensor 300. Charged grating or grid 352 may include a stack of meshes (e.g., wire meshes) that have particular charge. In some embodiments, as shown, a first grating or mesh is positively charged, a second grating or mesh may be grounded, and a third grating or mesh may be negatively charged. The positively charged mesh or grating may repel positively charged molecules or ions and the negatively charged mesh or grating may repel negatively charged molecules or ions. As a result, the only molecules that reach filter 335 may be neutral molecules. Of the neutral molecules that reach filter 335, only the radical species of a particular gas species may actually react with filter 335.

In some embodiments, in order to measure an amount of positively and/or negatively charged radical species, a pair of radical sensor devices may be used. A first radical sensor device may include the charged gratings or grids, and a second radical sensor device may not include the charged gratings or grids. All radical species of a target gas species may be detected by the second radical sensor device, and only neutral radical species of the target gas species may be detected by the first radical sensor device. A difference between the measurements of the two radical sensor devices may then be computed to determine an amount of the radical species detected by the second radical sensor that were attributable to charged radical species. The grating may be modified to only filter out positively charged molecules/ions or to only filter out negatively charged molecules. Accordingly, by combining two or more radical sensor devices, each with a different grating configuration (e.g., one not including any grating), an amount of positively charged radical species may be detected, an amount of negatively charged radical species may be detected, and/or an amount of neutral radical species may be detected.

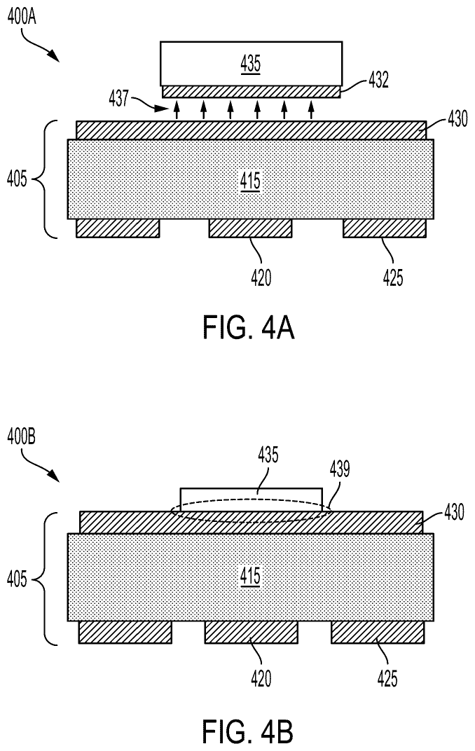

FIGS. 4A-4B are diagrams 400A and 400B illustrating the formation of a radical sensor of a radical sensor device, in accordance with embodiments of the present disclosure. In some embodiments, the radical sensor corresponds to radical sensor 204 of FIGS. 2A-2B. In some embodiments, the radical sensor device is an acoustic resonance sensor device. In some embodiments, the radical sensor includes a piezoelectric resonator. For example, the radical sensor can include a QCM resonator.

As shown in FIG. 4A, a radical sensor can include base structure 405 including radical sensor base 415 (e.g., piezoelectric layer), back electrode 420, back electrode edge 425 and front electrode 430, similar to radical sensor base 315 and electrodes 320, 325 and 330 as described above with reference to FIGS. 3A-3D. In some embodiments, front electrode 330 has a thickness that ranges between about 5 micrometers to about 30 micrometers.

As further shown, the radical sensor can include filter 435 disposed on layer 432. Filter 435 can be sensitive to reaction with a particular molecular species of a target gas species. The composition of filter 435 may depend on the application for which the radical sensor will be used. In some embodiments, filter 435 is composed of a material that reacts with a radical molecular species of a target gas, but that does not react to stable molecular species of the target gas. For example, the material of filter 410A may react to fluorine radicals, but may not react to stable molecules containing fluorine, such as F₂, C₂F₆, SF₆, NF₃, CF₄, CHF₃, CH₂F₂, etc. The material of filter 435 may also not react to other molecules that may be included in a gas flow, whether those other molecules are radical species or stable molecular species. For example, the material of filter 435 may react to fluorine radicals, but may not react to carbon radicals, nitrogen radicals, hydrogen radicals, etc. Alternatively, the material may only react to hydrogen radicals, or may only react to carbon radicals, or may only react to some other radical species.

In some embodiments, filter 435 includes a crystalline material. In some embodiments, the crystalline material is a monocrystalline material. In some embodiments, the crystalline material is a polycrystalline material. In some embodiments, the crystalline material includes SiO₂. In some embodiments, filter 435 has a thickness that ranges from about 5 micrometers to about 80 micrometers. In some embodiments, filter 435 has a diameter that ranges from about 4 millimeters to about 12 millimeters. In some embodiments, layer 432 includes the same material as front electrode 430 (e.g., Al). In some embodiments, layer 432 has a thickness that ranges between about 5 micrometers to about 30 micrometers.

In some embodiments, the crystalline material of filter 435 is cut from a base material. For example, the crystalline material can include a SiO₂ crystal (e.g., monocrystalline SiO₂ or polycrystalline SiO₂) cut from a base quartz material. In some embodiments, the crystalline material has a thickness that ranges from about 5 micrometers to about 50 micrometers.

In some embodiments, filter 435 includes a crystal structure having a number of grains. In some embodiments, a grain has a microstructure grain size selected to achieve a target filter lifetime depending on process conditions within which the radical sensor operates. In some embodiments, the microstructure grain size ranges between about 100 nanometers to about 50 micrometers. Additionally, increasing grain boundary size can increase the activation energy needed to induce a chemical reaction. Therefore, increasing grain boundary size can result in a greater amount or concentration of radical species being needed before seeing etching of the material of filter 435.

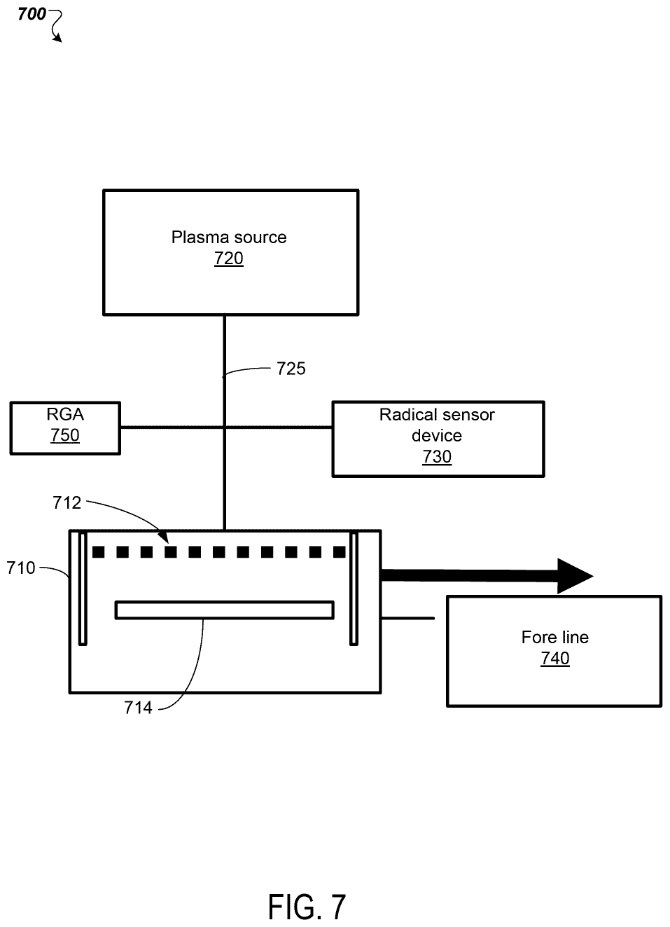

In some embodiments, and as shown, process 437 can be performed to bond layer 432 to front electrode 430. For example, process 437 can include performing a sintering process. As another example, process 437 can include performing an anneal process. As yet another example, process 437 can include using a bonding layer (e.g., glue) to bond layer 432 to front electrode 430. The bonding layer can have suitable properties to enable an acoustic wave to penetrate through an interface. Further details regarding process 437 are described above with reference to FIGS. 3A-3D and will be described in further detail below with reference to FIGS. 7-8B.

As shown in FIG. 4B, the processing of bonding base structure 405 to layer 432 can result in interface 439 between filter 435 and base structure 405. Interface 439 can be a high quality interface to enable an acoustic wave to travel through interface 439. For example, interface 439 can have a suitable porosity. In some embodiments, a high quality interface has a porosity of less than or equal to about 20%, a porosity of less than or equal to about 30%, or a porosity of less than or equal to 40%. Further details regarding interface 439 are described above with reference to FIGS. 3A-3D and will be described in further detail below with reference to FIGS. 7-8B.

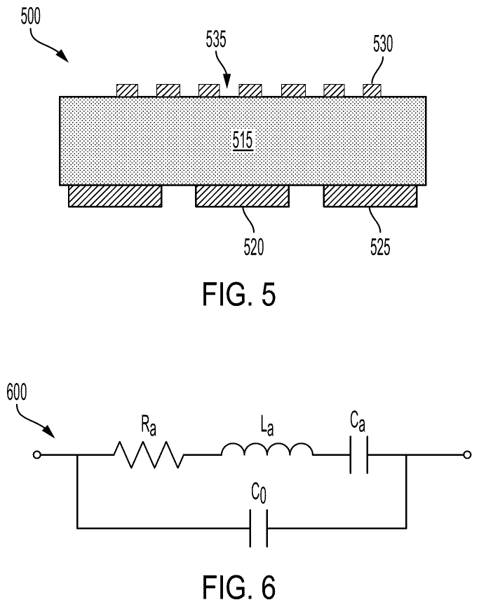

FIG. 5 illustrates an example radical sensor 500 of a radical sensor device, in accordance with embodiments of the present disclosure. In some embodiments, radical sensor 500 corresponds to radical sensor 204 of FIGS. 2A-2B. In some embodiments, the radical sensor device is an acoustic resonance radical sensor. In some embodiments, radical sensor 500 includes a piezoelectric resonator. For example, radical sensor 500 can include a QCM resonator. As shown, radical sensor 500 can include a base structure including radical sensor base 515, back electrode 520 and back electrode edge 525, similar to radical sensor base 315 and electrodes 320 325 as described above with reference to FIGS. 3A-3D.

Additionally, radical sensor 500 can include mesh 530 disposed on radical sensor base 515. In some embodiments, mesh 530 is formed by placing mesh 530 on the surface of radical sensor base 515. In some embodiments, mesh 530 is formed by depositing mesh 530 on the surface of radical sensor base 515. Mesh 530 can include any suitable material in accordance with embodiments described herein. Examples of suitable materials include Al, Au, Ni, etc. In some embodiments, mesh 530 has an approximately 30% opening. In some embodiments, a thickness of mesh 530 is less than or equal to about 5 millimeters. In some embodiments, a thickness of mesh 530 is less than or equal to about 3 millimeters. Exposed regions 535 of radical sensor base 515 can thus react with radical species. Further details regarding radical sensor 500 are described above with reference to FIGS. 3A-3D and will be described in further detail below with reference to FIGS. 7-8B.

A radical sensor including a piezoelectric resonator (e.g., QCM resonator) can be represented by a simple equivalent circuit 600 for electrical analysis, as shown in FIG. 6. The mechanical behavior of the radical sensor can be represented by an electrical equivalent model as shown. This is the so-called the Butterworth van Dyke (BVD) electrical model. In the motional arm (the upper branch) of the BVD model, it consists of three components that determine the series resonance frequency of the quartz crystal plate. Rₐ corresponds to the energy dissipation due to mechanical coupling between the crystal and its holder. For some applications, added mass load on the crystal surface also causes Rₐ to increase. Lₐ corresponds to the mass being displaced during oscillation. For some applications, the total mass includes that of the crystal, the electrodes, and the deposited thin film materials. Cₐ corresponds to the stored energy in the piezoelectric resonator that is related to the elastic properties of quartz, electrodes, and the deposited materials. The parasitic capacitance C₀ represents the total static capacitances of the crystal electrodes, the holder, and the connecting cable.

FIG. 7 is a diagram of an example substrate processing system (“system”) 700, according to some embodiments. As shown, system 700 can include processing chamber 710, plasma source 720, radical sensor device 730, and radical sensor fore line (“fore line”) 740. For example, processing chamber 710 can include gas distribution assembly (e.g., showerhead) 712. In some embodiments, processing chamber 710 is a deposition chamber. In some embodiments, processing chamber 710 is an etch chamber. In some embodiments, plasma source 720 is an RPS. In some embodiments, and as shown, system 700 can include residual gas analyzer (“RGA”) 750. RGA 750 can analyze residual gases within processing chamber 710. For example, RGA 750 can include a mass spectrometer.

A plasma-based process can be performed within system 700. For example, the plasma-based process can be used to process substrate 714 placed within processing chamber 710. In some embodiments, the plasma-based process is a clean process. To perform the plasma-based process, plasma source 720 can use one or more gases to generate a plasma. The plasma generated by plasma source 720 during the plasma-based process can include radical species. Delivery line 725 can be connected to plasma source 720 for delivering the radical species to processing chamber 710 for use during the plasma-based process. Radical sensor device 730 can detect the radical species (e.g., being delivered through delivery line 725 and/or within processing chamber 730).

At least one component of system 700 can be coated with a protective coating to prevent radical species recombination and extend radical species lifetime. In some embodiments, the at least one component includes at least one of: processing chamber 710, gas distribution assembly 714, or a component connected to plasma source 720 (e.g., delivery line 725). In some embodiments, the radical species includes a fluorine radical. In some embodiments, the protective coating includes fluorinated Mg. For example, the protective coating can include a layer of MgF₂. Further details regarding system 700, including components of system 700 coated with a protective coating to prevent radical species recombination and extend radical species lifetime, will now be described below with reference to FIGS. 8-11.

FIG. 8 is a flow chart of a method 800 for forming a protective coating on at least one component of a substrate processing system for minimizing radical species recombination and extending radical species lifetime, according to some embodiments, in accordance with some embodiments.

At block 805, at least one component of a substrate processing system is obtained. The at least one component can be used during a plasma-based process performed within the substrate processing system. In some embodiments, the plasma-based process is an etch process or clean process. In some embodiments, the at least one component includes at least one of: a processing chamber wall, a gas distribution assembly (e.g., showerhead) of a processing chamber, a plasma source, or a component connected to a plasma source. For example, if the plasma source is an RPS, then the one or more components connected to the plasma source can include one or more delivery lines connecting the RPS to the processing chamber.

At block 810, a protective coating is formed on a surface of the at least one component to prevent recombination of at least one radical species. Additionally, the protective coating can be used to extend a lifetime of at least one radical species. For example, the at least one radical species can be included in a plasma generated by the plasma source during the plasma-based process. In some embodiments, the radical species includes a fluorine radical. In some embodiments, the protective coating includes fluorinated Mg. For example, the protective coating can include a layer of MgF₂.

Various processes can be used to form a protective coating on a surface of a component of a substrate processing system. In some embodiments, forming a protective coating on a surface of a component of a substrate processing system includes depositing the protective coating on the surface of the component. In some embodiments, the component includes a base material. In some embodiments, the base material includes a metal material. For example, the metal material can include aluminum (Al), stainless steel, etc. In some embodiments, the metal is an alloy (e.g., Al alloy). In some embodiments, the base material includes a ceramic material. Examples of ceramic materials that can be used to form the base material include Al₂O₃, AlN, SiC, etc. In some embodiments, depositing the protective coating on the surface of the component can include using at least one of: ALD, PVD, CVD, IAD, EB-IAD, etc. For example, if the protective coating includes Mg and F, depositing the protective coating on the surface of the component can include depositing a layer of MgF₂ on the surface of the component using at least one of: ALD, CVD PVD, IAD or EB-IAD. In some embodiments, depositing the protective coating on the surface of the component can include using laser ablation to deposit the protective coating on the surface of the component. For example, if the protective coating includes Mg and F, depositing the protective coating on the surface of the component using laser ablation can include using laser ablation to deposit a layer of MgF₂ on the surface of the component.

For example, depositing the protective coating on the surface of the component using ALD can include depositing a first adsorption layer on the surface of the component by pulsing one or more precursors (e.g., magnesium precursors) into an ALD chamber, and introducing one or more reactants (e.g., fluorine-containing reactants) into the ALD chamber to form the protective coating. Excess precursor(s) can be flushed out of the ALD chamber before the one or more reactants are introduced into the ALD chamber and subsequently flushed out. The final thickness of the protective coating can be dependent on the number of reaction cycles that are run, because each reaction cycle will grow a layer of a certain thickness that may be one atomic layer or a fraction of an atomic layer. ALD can be used to deposit the protective coating at a relatively low temperature (e.g., about 25° C. to about 350° C.) so that it does not damage or deform any materials of component. Additionally, ALD can be used to deposit the protective coating within complex features (e.g., high aspect ratio features). Furthermore, ALD can be used to deposit the protective coating to be a thin layer (e.g., having a thickness of less than or equal to about 1 μm) that have low porosity (e.g., less than or equal to about 5% porosity), which may eliminate crack formation during the formation of the protective coating.

In some embodiments, an adhesion layer is formed on the component, and the protective coating is deposited on the adhesion layer (e.g., using ALD). The adhesion layer can improve the adhesive strength between the surface of the component and the protective coating. The adhesion layer can also reduce stress by being formed from a material having a coefficient of thermal expansion (CTE) value that is between the CTE of the protective coating and the CTE of the component to mitigate any potential mismatch in the CTE between the protective coating and the CTE of the component. For example, the component being coated by the protective coating may include a metal material. For example, some Al-containing materials can have a CTE of about 22-25 ppm/K, and stainless steel can have a CTE of about 13 ppm/K. In such embodiments, the adhesion layer mitigates the CTE differential between the protective coating and component to reduce the protective coating's susceptibility to cracking upon thermal cycling which could result from a CTE mismatch. The adhesion layer can include any suitable material(s). In some embodiments, the adhesion layer is formed a ceramic material. Examples of suitable ceramic materials for the adhesion layer include Al₂O₃, silicon dioxide (SiO₂), Y₂O₃, zirconium oxide (ZrO₂), etc.

In some embodiments, forming a protective coating on a surface of a component of a substrate processing system includes annealing the component to bring first atoms to the surface of the component, and introducing second atoms to the surface of the component to form the protective coating on the surface of the component. More specifically, the component can include the first atoms disposed within a base material. In some embodiments, the base material includes a metal material. For example, the base material can include Al (e.g., an Al alloy). In some embodiments, introducing the second atoms to the surface of the component includes fluorinating the surface of the component. More specifically, a first atom is a first atom of the protective coating, and a second atom is a second atom of the protective coating. For example, if the protective coating includes fluorinated Mg (e.g., MgF₂), then a first atom can be Mg and a second atom can be F. Any suitable compound can be used to introduce the second atoms to the surface of the component. For example, in the case of fluorination, the compound can include hydrogen fluoride (HF) having a concentration of greater than or equal to 0.5%. The anneal can be performed at any suitable temperature in accordance with embodiments described herein. The anneal temperature can be determined based on the material of the component (e.g., base material including Al). In some embodiments, the anneal temperature ranges from about 200° C. to about 2000° C. In some embodiments, the anneal temperature ranges from about 400° C. to about 800° C. The anneal can be performed for any suitable amount of time in accordance with embodiments described herein. For example, the anneal time can range from about 30 minutes to about 180 minutes.

In some embodiments, forming a protective coating on a surface of a component of a substrate processing system includes depositing, on the surface of the component, a film including first atoms, and introducing second atoms to the film to form the protective coating on the surface of the component. In some embodiments, the component is formed from a metal material. For example, the metal material can include Al (e.g., Al alloy). In some embodiments, the component is formed from a ceramic material. In some embodiments, depositing the film on the surface of the component can include using at least one of: ALD, PVD, CVD, IAD or EB-IAD. In some embodiments, introducing the second atoms to the film includes fluorinating the film. More specifically, a first atom is a first atom of the protective coating, and a second atom is a second atom of the protective coating. For example, if the protective coating includes fluorinated Mg, then a first atom can be Mg and a second atom can be F. Any suitable compound can be used to introduce the second atoms to the surface of the component. For example, in the case of fluorination, the compound can include HF having a concentration of greater than or equal to 0.5%.

In some embodiments, forming a protective coating on a surface of a component of a substrate processing system includes performing particle implantation (e.g., ion implantation) to implant first atoms into a base material of the component to form a modified base material, and introducing second atoms to the modified base material to form the protective coating. In some embodiments, the base material is a metal material. For example, the metal material can include Al. In some embodiments, the metal is an alloy (e.g., Al alloy). The particle implantation can be performed at any suitable temperature in accordance with embodiments described herein. In some embodiments, the particle implantation is a low-temperature process. In some embodiments, introducing the second atoms to the film includes fluorinating the film. More specifically, a first atom is a first atom of the protective coating, and a second atom is a second atom of the protective coating. For example, if the protective coating includes fluorinated Mg, then a first atom can be Mg and a second atom can be F. Any suitable compound can be used to introduce the second atoms to the surface of the component. For example, in the case of fluorination, the compound can include HF having a concentration of greater than or equal to 0.5%.

In some embodiments, a component of a substrate processing system is formed from a base material including first atoms, and forming a protective coating on a surface of the component includes introducing second atoms to the surface of the component. More specifically, a first atom is a first atom of the protective coating, and a second atom is a second atom of the protective coating. In some embodiments, introducing the second atoms to the surface of the component includes fluorinating the surface of the component. For example, if the protective coating includes fluorinated Mg, then the base material can include bulk Mg, a first atom can be Mg and a second atom can be F. In some embodiments, introducing the second atoms to the surface of the component includes fluorinating the surface of the component. For example, if the protective coating includes fluorinated Mg, then the base material can include bulk Mg, a first atom can be Mg and a second atom can be F. Any suitable compound can be used to introduce the second atoms to the surface of the component. For example, in the case of fluorination, the compound can include HF having a concentration of greater than or equal to 0.5%.

In some embodiments, a component of a substrate processing system is formed by using an additive manufacturing process to create a base material. For example, the base material can include a metal material, a ceramic material, etc., as described above. In some embodiments, the additive manufacturing process is a three-dimensional (3D) printing process. Then, the protective coating can be formed on the surface of the component using any suitable process. For example, forming the protective coating can include depositing the protective coating on the surface of the component (e.g., on the base material or on an adhesion layer disposed on the base material). As another example, the base material can include first atoms, and forming the protective coating can include annealing the base material to bring the first atoms to the surface of the base material, and introducing second atoms to the surface of the base material to form the protective coating. As another example, forming the protective coating can include depositing, on the surface of the component (e.g., on the base material or on an adhesion layer disposed on the base material), a film including first atoms, and introducing second atoms to the film to form the protective coating. As another example, forming the protective coating can include performing particle implantation (e.g., ion implantation) to implant first atoms into the base material of the component to form a modified base material, and introducing second atoms to the modified base material to form the protective coating. As another example, the base material can include first atoms, and forming the protective coating can include introducing second atoms to the surface of the component. Further details regarding blocks 805 and 810 are described above with reference to FIGS. 1 and 7 and will now be described in further detail below with reference to FIG. 9.

FIG. 9 is a diagram of an example component 900 of a substrate processing system, according to some embodiments. As shown, component 900 can include base structure 910 including base component 912. Base component 912 can include any suitable material. In some embodiments, base component 912 includes a metal material. For example, base component 912 can include an Al-containing material (e.g., an Al alloy), a Mg-containing material (e.g., bulk Mg), stainless steel, etc. In some embodiments, base component 912 includes a ceramic material. For example, base component 912 can include Al₂O₃. In some embodiments, base component 912 includes at least one of: a processing chamber wall, a gas distribution assembly (e.g., showerhead), a plasma source, or a component connected to the plasma source. For example, if the plasma source is an RPS, then base component 912 can include a delivery line that connects the RPS to a processing chamber.

As further shown, protective coating 920 is disposed on base structure 910. Protective coating 920 can prevent radical species recombination and can extend radical species lifetime with respect to radicals used during a plasma-based process. For example, the at least one radical species can be included in a plasma generated by the plasma source (e.g., RPS) during a plasma-based process. In some embodiments, the radical species includes a fluorine radical. In some embodiments, protective coating 920 includes fluorinated Mg. For example, the protective coating can include a layer of MgF₂.

In some embodiments, protective coating 920 has a porosity of less than or equal to about 5%. In some embodiments, protective coating 920 has a porosity of less than or equal to about 1%. In some embodiments, protective coating 920 has a porosity of less than or equal to about 0.1%. In some embodiments, protective coating 920 has a thickness that ranges from about 10 nanometers to about 2 micrometers. In some embodiments, the roughness of protective coating 920 ranges from about 0.1 microinches to 200 microinches, from about 0.5 microinches to about 50 microinches, from about 2 microinches to about 30 microinches, from about 5 microinches to about 20 microinches, from about 75 microinches to about 150 microinches, or from about 30 microinches to about 100 microinches, or any sub-range or single value therein. In certain embodiments, the microhardness of protective coating 920 is at least two times greater than the microhardness of stainless steel and/or at least four times greater than that of Al₂O₃. The above microhardness values refer to the force exerted on protective coating 920 to observe a first failure (or first crack formation) of the protective coating.

Various processes can be used to form protective coating 920 on base component 912, as described above with reference to FIG. 8. In some embodiments, protective coating 920 is formed directly on base component 912.

In some embodiments, and as shown in FIG. 9, base structure 910 further includes adhesion layer 914 formed on base component 912, and protective coating 920 is formed on adhesion layer 914 (e.g. using ALD). Adhesion layer 914 can improve the adhesive strength between the surface of the component and the protective coating. Adhesion layer 914 can also reduce stress by being formed from a material having CTE value that is between the CTE of protective coating 920 and the CTE of base component 910 to mitigate any potential mismatch in the CTE between protective coating 920 and the CTE of base component 910. In such embodiments, adhesion layer 914 can mitigate the CTE differential between protective coating 920 and base component 910 to reduce the susceptibility of protective coating 920 to cracking upon thermal cycling which could result from a CTE mismatch. For example, base component 910 may include a metal material. For example, some Al-containing materials can have a CTE of about 22-25 ppm/K. As another example, stainless steel can have a CTE of about 13 ppm/K. Adhesion layer 914 can include any suitable material(s). In some embodiments, adhesion layer 914 is formed from a ceramic material. Examples of suitable ceramic materials for adhesion layer 914 include Al₂O₃, SiO₂, Y₂O₃, ZrO₂, etc.

In some embodiments, adhesion layer 914 has a porosity of less than or equal to about 5%. In some embodiments, adhesion layer 914 has a porosity of less than or equal to about 1%. In some embodiments, adhesion layer 914 has a porosity of less than or equal to about 0.1%. In some embodiments, adhesion layer 914 has a thickness that ranges from about 10 nanometers to about 2 micrometers.

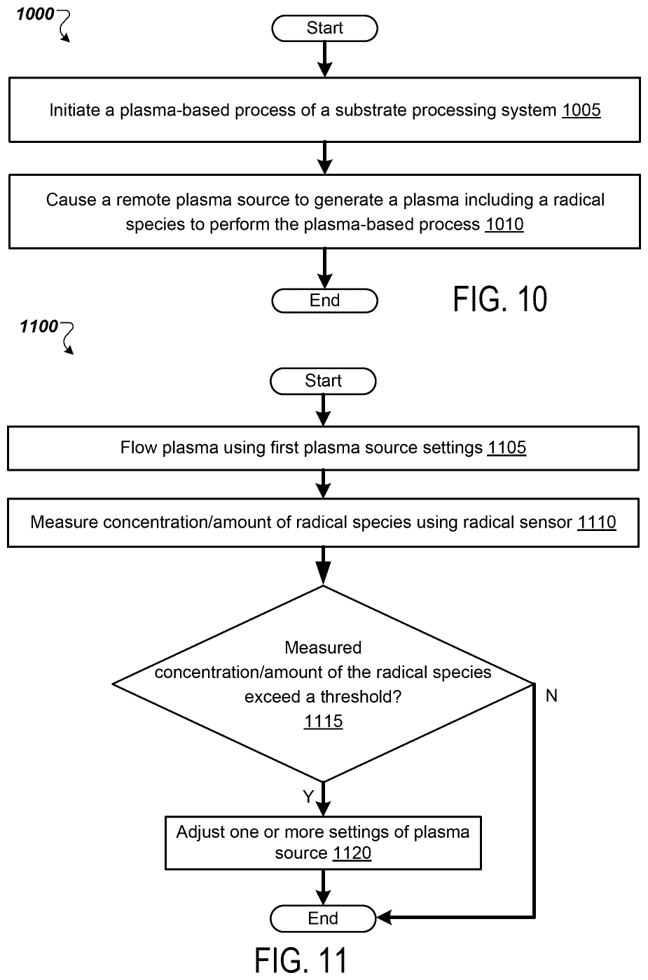

FIG. 10 is a flow chart of a method 1000 for utilizing substrate processing systems for minimizing radical species recombination and extending radical species lifetime, according to some embodiments.

At block 1005, processing logic initiates a plasma-based process of a substrate processing system. In some embodiments, the plasma-based process is a clean process to clean one or more components of the substrate processing system (e.g., a processing chamber).

At block 1010, processing logic causes a plasma source of the substrate processing system to generate a plasma including radical species to perform the plasma-based process. In some embodiments, the plasma source is an RPS external to the processing chamber. The plasma source can generate the plasma using one or more gases. In some embodiments, the one or more gases include one or more halogen-containing gases. For example, if the radical species includes a fluorine radical, then the one or more gases can include one or more fluorine-containing gases. Examples of fluorine-containing gases include F₂, CF₄, C₂F₆, SF₆, NF₃, HF₃, CHF₃, CH₂F₂, SiF₄, etc.

In some embodiments, the flow rate of a plasma gas used to generate the plasma ranges from about 100 standard cubic centimeters per minute (sccm) to about 6000 sccm. In some embodiments, the flow rate of a plasma gas used to generate the plasma ranges from about 200 sccm to about 500 sccm. In some embodiments, the plasma gas includes a halogen-containing gas. For example, the plasma gas can include a fluorine-containing gas. Examples of plasma gases are described above. In some embodiments, the pressure is greater than or equal to about 1 Torr. In some embodiments, the flow rate of an inert gas used to generate the plasma is greater than or equal to about 500 sccm. In some embodiments, the flow rate of the inert gas is greater than or equal to about 1000 sccm.

In some embodiments, the substrate processing system can include at least one component coated with a protective coating that prevents radical species recombination and extends radical species lifetime. In some embodiments, the protective coating includes fluorinated Mg (e.g., MgF₂). In some embodiments, the at least one component includes at least one of: a processing chamber wall, a gas distribution assembly (e.g., showerhead), the plasma source, or a component connected to the plasma source. For example, if the plasma source is an RPS, then the component connected to the plasma source can include a delivery line connecting the RPS to the processing chamber. Further details regarding blocks 1005-1010 are described above with reference to FIGS. 1-9.

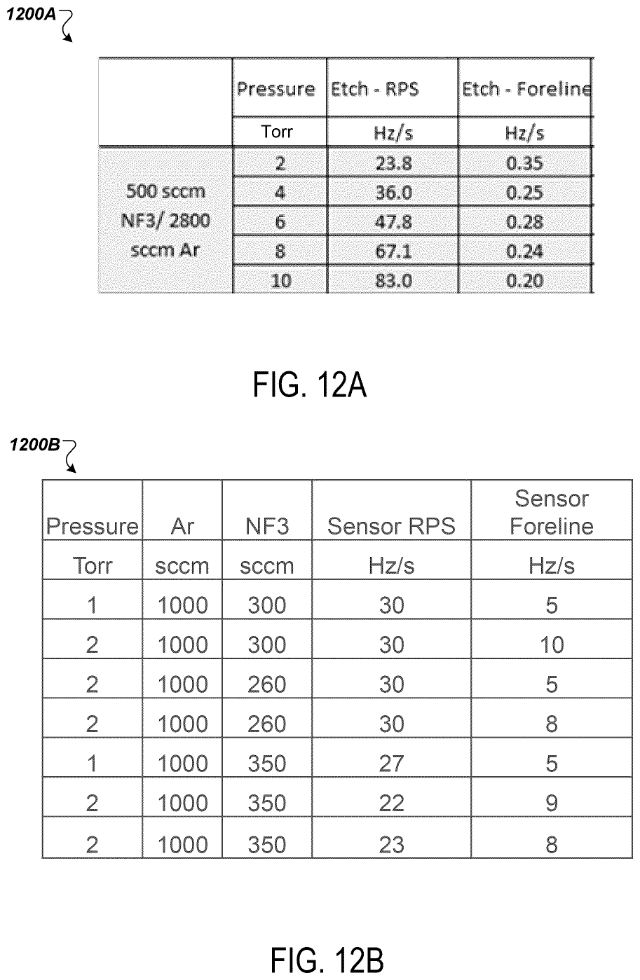

As will be described in further detail below with reference to FIGS. 11-12B, a radical sensor device (e.g., as described hereinabove) can be used to detect the radical species by measuring a concentration or amount of the radical species. The concentration or amount of the radical species can be used to determine one or more parameters of the plasma-based process (e.g., etch rate), which can be used to control one or more settings of the plasma source.

FIG. 11 is a flow chart of a method 1100 for utilizing a radical sensor device, in accordance with some embodiments. At block 1105, a manufacturing system flows a plasma using first plasma source settings. The plasma may be generated by a remote plasma source (e.g., a plasma source external to a process chamber) or by a local plasma source (e.g., a plasma source internal to a process chamber). At block 1110, a radical sensor (e.g., as described hereinabove) is used to measure a concentration or amount of radical species of a target gas species in the plasma. The radical species of a target gas species may react with a filter on the radical sensor, causing a mass on a sensing surface of the radical sensor to change. The density and/or mass of the filter may be known, and a change in the mass of the filter may be detected based on a change in the resonant frequency of a piezoelectric material of the radical sensor. This change in mass together with knowledge about the mass of the materials that make up the filter may be used to determine a number of radical species that reacted with the filter, and thus the concentration and/or amount of radical species.

At block 1115, processing logic determines whether the measured concentration/amount of radical species exceeds a threshold. For example, processing logic can determine whether the measured concentration/amount of radical species varies from a target concentration/amount of the radical species by more than a threshold amount (e.g., if a difference between the target concentration and the detected concentration is more than a difference threshold).

If the difference exceeds a difference threshold, the method continues to block 1120 and one or more settings of the plasma source are adjusted. For example, the plasma power may be increased in increase an amount of radical species that are included in the plasma or may be decreased to reduce an amount of radical species that are included in the plasma. If the difference is less than the difference threshold, then the method may end.

FIG. 12A is a chart 1200A illustrating example measurements taken by a radical sensor without using a protective coating, according to some embodiments. Chart 1200A illustrates etch rates measured by at least one radical sensor at an RPS (“Etch—RPS”) and etch rates measured by the at least one radical sensor at an RPS fore line (“Etch—Foreline”) at flow rates of a fluorine-containing gas (e.g., NF₃) of about 500 sccm and an inert gas (e.g., Ar) of about 2800 sccm, at pressures ranging from about 2 torr to about 10 torr. For example, for a flow rate of the fluorine-containing gas of 500 sccm at a pressure of about 2 torr, the etch rate measured by the at least one radical sensor at the RPS is about 23.8 Hertz/second (Hz/s) and the etch rate measured by the at least one radical sensor at the RPS fore line is about 0.35 Hz/s. As shown, without using a protective coating as described herein, the etch rate measured by the at least one radical sensor at the RPS fore line can be less than or equal to about 1/40 of the etch rate measured by the at least one radical sensor at the RPS when a protective coating is not used (e.g., 1.16 Hz/s is about 1/40 of 46.3 Hz/s).

FIG. 12B is a chart 1200B illustrating example measurements taken by a radical sensor using a protective coating, according to some embodiments. Chart 1200B illustrates etch rates measured by at least one radical sensor at an RPS (“Sensor RPS”) and etch rates measured by the at least one radical sensor at an RPS fore line (“Sensor Foreline”) at flow rates of a fluorine-containing gas (e.g., NF₃) ranging from about 260 sccm to about 350 sccm and an inert gas (e.g., Ar) of about 1000 sccm, at pressures ranging from about 1 torr to about 2 torr. For example, for a flow rate of the fluorine-containing gas of 350 sccm at a pressure of about 2 torr, the etch rates measured by the at least one radical sensor at the RPS is about 22 Hz/s and about 23 Hz/s and the etch rate measured by the at least one radical sensor at the RPS fore line is about 9 Hz/s and about 8 Hz/s, respectively. As shown, using a protective coating as described herein, the etch rate measured by the at least one radical sensor at the fore line is greater than or equal to about ⅙ of the etch rate measured by the at least one radical sensor at the RPS when a protective coating is used (e.g., 5 Hz/s is about ⅙ of 30 Hz/s). Thus, the use of the protective coating has been shown to reduce radical species recombination and extend radical species lifetime.

Unless specifically stated otherwise, terms such as “first,” “second,” “third,” “fourth,” etc. as used herein are meant as labels to distinguish among different elements and may not have an ordinal meaning according to their numerical designation.

Examples described herein also relate to an apparatus for performing the methods described herein. This apparatus may be specially constructed for performing the methods described herein, or it may include a general purpose system selectively configured to perform methods described herein.

The terms “over,” “under,” “between,” “disposed on,” “support,” and “on” as used herein refer to a relative position of one material layer or component with respect to other layers or components. For example, one layer disposed on, over, or under another layer may be directly in contact with the other layer or may have one or more intervening layers. Moreover, one layer disposed between two layers may be directly in contact with the two layers or may have one or more intervening layers. Similarly, unless explicitly stated otherwise, one feature disposed between two features may be in direct contact with the adjacent features or may have one or more intervening layers.

The above description is intended to be illustrative, and not restrictive. Although the present disclosure has been described with references to specific illustrative examples and implementations, it will be recognized that the present disclosure is not limited to the examples and implementations described. The scope of the disclosure should be determined with reference to the following claims, along with the full scope of equivalents to which the claims are entitled.

What is claimed is:

1. A system comprising:
a plasma source to generate a plasma comprising radical species;
at least one component, associated with the plasma source, coated with a protective coating comprising fluorinated magnesium that mitigates recombination of the radical species; and
a radical sensor comprising a filter disposed on a piezoelectric material to selectively react with the radical species.

2. The system of claim 1, wherein:
the plasma source is a remote plasma source;
the system further comprises a processing chamber coupled to the remote plasma source via one or more gas delivery lines; and
at least one of: the one or more gas deliver lines or a wall of the processing chamber is coated with the protective coating that mitigates recombination of the radical species.

3. The system of claim 1, wherein the at least one component comprises a metal, and wherein the protective coating is formed on a surface of the metal.

4. The system of claim 1, wherein the at least one component comprises a ceramic, and wherein the protective coating is formed on a surface of the ceramic.

5. The system of claim 1, wherein the piezoelectric material comprises a quartz crystal, and wherein the radical sensor comprises a quartz crystal microbalance (QCM) resonator.

6. The system of claim 1, wherein the at least one component is further coated with an adhesion layer that is between the protective coating and a body of the at least one component, and wherein the adhesion layer comprises at least one of aluminum oxide, silicon dioxide, yttrium oxide or zirconium oxide.

7. The system of claim 6, wherein:
the protective coating has a porosity of less than about 5% and has a thickness that ranges from about 10 nanometers to 2 about micrometers; and
the adhesion layer has a porosity of less than about 5% and has a thickness of about 10 nanometers to about 2 micrometers.

8. A method comprising:
obtaining a component associated with a plasma source; and
forming, on a surface of the component, a protective coating comprising fluorinated magnesium that prevents recombination of at least one radical species.

9. The method of claim 8, wherein forming the protective coating on the surface of the component comprises depositing the protective coating on the surface of the component using at least one of: atomic layer deposition (ALD), physical vapor deposition (PVD), chemical vapor deposition (CVD), or ion-beam assisted deposition.

10. The method of claim 8, wherein forming the protective coating on the surface of the component comprises depositing the protective coating on the surface of the component using laser ablation.

11. The method of claim 8, wherein the component comprises magnesium disposed within a base material, and wherein forming the protective coating on the surface of the component comprises:
annealing the component to bring the magnesium to the surface of the component; and
introducing fluorine to the surface of the component to react with the magnesium and form the protective coating comprising fluorinated magnesium on the surface of component.

12. The method of claim 8, wherein forming the protective coating on the surface of the component further comprises:
depositing, on the surface of the component, a film comprising magnesium using at least one of: atomic layer deposition (ALD), physical vapor deposition (PVD), chemical vapor deposition (CVD), or ion-beam assisted deposition; and
introducing fluorine to the film to form the protective coating comprising fluorinated magnesium on the surface of the component.

13. The method of claim 8, wherein forming the protective coating on the surface of the component comprises:
performing ion implantation to implant magnesium into a base material of the component to form a modified base material; and
introducing fluorine to the modified base material to form the protective coating comprising fluorinated magnesium.

14. The method of claim 8, wherein the component comprises a base material comprising magnesium, and wherein forming the protective coating on the surface of the component comprises introducing fluorine to a surface of component.

15. A method comprising:
initiating a plasma-based process of a substrate processing system; and
causing a plasma source to generate a plasma comprising radical species to perform the plasma-based process, wherein the plasma source is associated with one or components coated with a protective coating comprising fluorinated magnesium that prevents recombination of the radical species.

16. The method of claim 15, wherein the radical species comprises a fluorine radical.

17. The method of claim 16, wherein the plasma is generated using a fluorine-containing gas having a flow rate that ranges from about 200 standard cubic centimeters per minute (sccm) to about 500 sccm.

18. The method of claim 15, further comprising causing a radical sensor device to measure an amount of the radical species.

19. The method of claim 18, further comprising adjusting, based on the amount of the radical species, one or more parameters used to generate the plasma comprising the radical species to perform the plasma-based process.

20. The method of claim 15, further comprising causing at least one radical sensor device to measure a first etch rate at the plasma source and a second etch rate at a fore line associated with the plasma source, and wherein the second etch rate is greater than or equal to about ⅙ of the first etch rate.
